(19) United States
(12) Patent Application Publication
(10) Pub. No.: US 2026/0239736 A1
(43) Pub. Date: Aug. 13, 2026

(54) SEMICONDUCTOR DEVICE AND MANUFACTURING METHOD THEREOF

(71) Applicant: TAIWAN SEMICONDUCTOR MANUFACTURING COMPANY LTD., HSINCHU (TW)

(72) Inventors: SHIH-CHANG CHEN, CHIAYI COUNTY (TW); WEN-CHAO SHEN, HSINCHU COUNTY (TW)

(21) Appl. No.: 19/050,144

(22) Filed: Feb. 11, 2025

(51) Int. Cl. H10D 84/90; H03K 19/20

(52) U.S. Cl. CPC H10D 84/966; H10D 84/951; H03K 19/20

(57) ABSTRACT

The present disclosure provides a semiconductor device and a method of manufacturing a semiconductor device. The method includes providing the semiconductor device comprising a fin structure protruding from a substrate, wherein a gate trench is between adjacent fins of the fin structure; forming a first gate structure in the first gate trench; and forming a second gate structure in the first gate trench and above the first gate structure.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides numerous benefits, such as increased production efficiency and reduced costs.

In addition to the reduction in geometric size, there is also a need for strategies that further enhance functional density.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 illustrates a flowchart of an example method for making a semiconductor device in accordance with some embodiments of the present disclosure.

FIGS. 2A, 2B, 2C, 2D, 2E, 2F, 2G, 2H, 2I, 2J, 2K, and 2L illustrate cross-sectional views of the example semiconductor device at intermediate stages of the method of FIG. 1 in accordance with some embodiments of the present disclosure.

FIG. 3 is a top view illustrating a semiconductor device in accordance with some embodiments of the present disclosure.

FIG. 3A is a cross-sectional view illustrating a semiconductor device in accordance with some embodiments of the present disclosure.

FIG. 3B is a cross-sectional view illustrating a semiconductor device in accordance with some embodiments of the present disclosure.

FIG. 3C is a cross-sectional view illustrating a semiconductor device in accordance with some embodiments of the present disclosure.

FIG. 4A is a schematic diagram illustrating a semiconductor device in accordance with some embodiments of the present disclosure.

FIG. 4B illustrates circuit diagrams of devices including a semiconductor device in accordance with some embodiments of the present disclosure.

FIG. 5 illustrates a flowchart of an example method for making a semiconductor device in accordance with some embodiments of the present disclosure.

FIGS. 5A, 5B, 5C, 5D, and 5E illustrate cross-sectional views of the example semiconductor device at intermediate stages of the method of FIG. 5 in accordance with some embodiments of the present disclosure.

FIG. 6 is a top view illustrating a semiconductor device in accordance with some embodiments of the present disclosure.

FIG. 6A is a cross-sectional view illustrating a semiconductor device in accordance with some embodiments of the present disclosure.

FIG. 6B is a cross-sectional view illustrating a semiconductor device in accordance with some embodiments of the present disclosure.

FIG. 6C is a cross-sectional view illustrating a semiconductor device in accordance with some embodiments of the present disclosure.

FIG. 6D is a cross-sectional view illustrating a semiconductor device in accordance with some embodiments of the present disclosure.

FIG. 7 is a cross-sectional view illustrating a semiconductor device in accordance with some embodiments of the present disclosure.

FIG. 8 is a cross-sectional view illustrating a semiconductor device in accordance with some embodiments of the present disclosure.

FIG. 9 is a top view illustrating a semiconductor device in accordance with some embodiments of the present disclosure.

FIG. 9A is a cross-sectional view illustrating a semiconductor device in accordance with some embodiments of the present disclosure.

FIG. 9B is a cross-sectional view illustrating a semiconductor device in accordance with some embodiments of the present disclosure.

FIG. 10 is a schematic diagram illustrating a semiconductor device in accordance with some embodiments of the present disclosure.

FIG. 11 illustrates circuit diagrams of devices including a semiconductor device in accordance with some embodiments of the present disclosure.

FIG. 12 is a top view illustrating a semiconductor device in accordance with some embodiments of the present disclosure.

FIG. 12A is a cross-sectional view illustrating a semiconductor device in accordance with some embodiments of the present disclosure.

FIG. 12B is a cross-sectional view illustrating a semiconductor device in accordance with some embodiments of the present disclosure.

FIG. 13 is a cross-sectional view illustrating a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

Logic circuits may include multiple transistors electrically connected in parallel, which occupy a relatively large area, thereby limiting design layout flexibility and reducing functional density.

The present disclosure provides a semiconductor device and its method of fabrication. The semiconductor device may include a plurality of gate structures (including gate electrodes and gate dielectric layers) and an active region (e.g., semiconductor fin(s), multiple sheets, or wires). The gate structures may be configured to control (or generate) individual channels in the active region. Each of the gate structures and a respective channel is a part of one transistor. If at least one of the channels is generated, the semiconductor device would be turned on; only if none of the channels is generated, the semiconductor device would be turned off. That is, the semiconductor device functions as multiple transistors electrically connected in parallel but has a relatively small area. The design layout flexibility can be enhanced, enabling increased functional density.

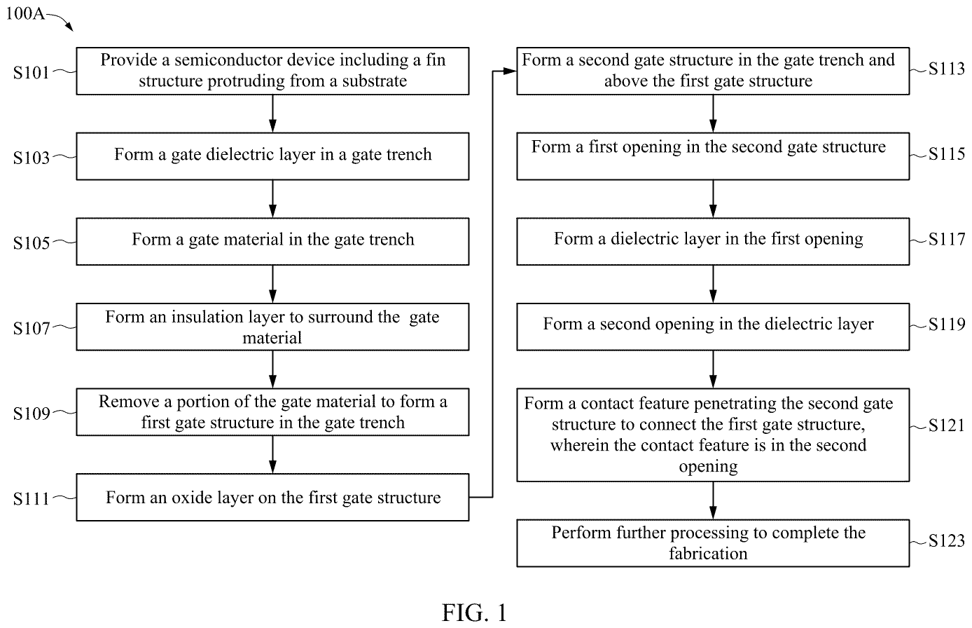

FIG. 1 illustrates a flow chart of a method 100A for forming a semiconductor device 200 in accordance with some embodiments of the present disclosure. Method 100A is merely an example and is not intended to limit the present disclosure beyond what is explicitly recited in the claims. Additional operations can be performed before, during, or after operations of method 100A, and some operations described can be replaced, eliminated, or moved around for additional embodiments of the method.

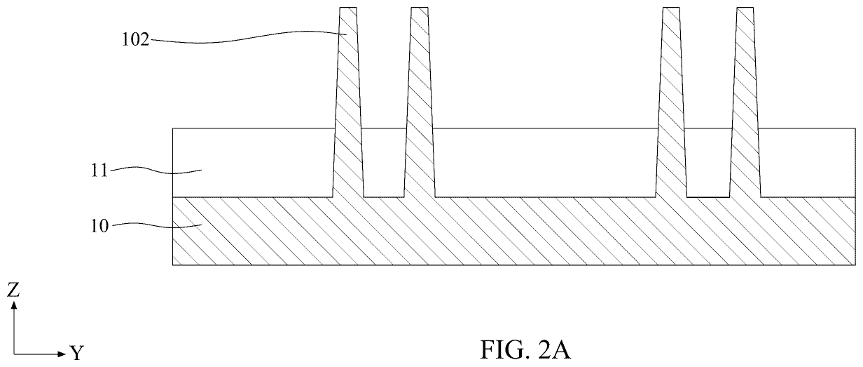

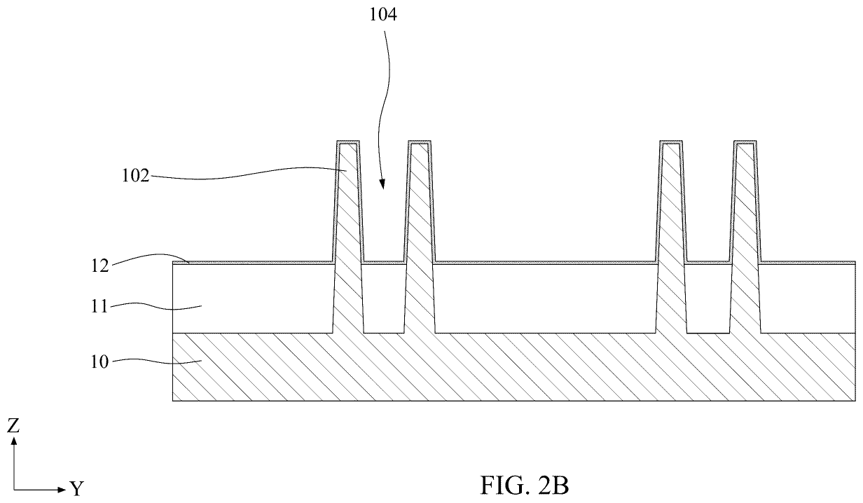

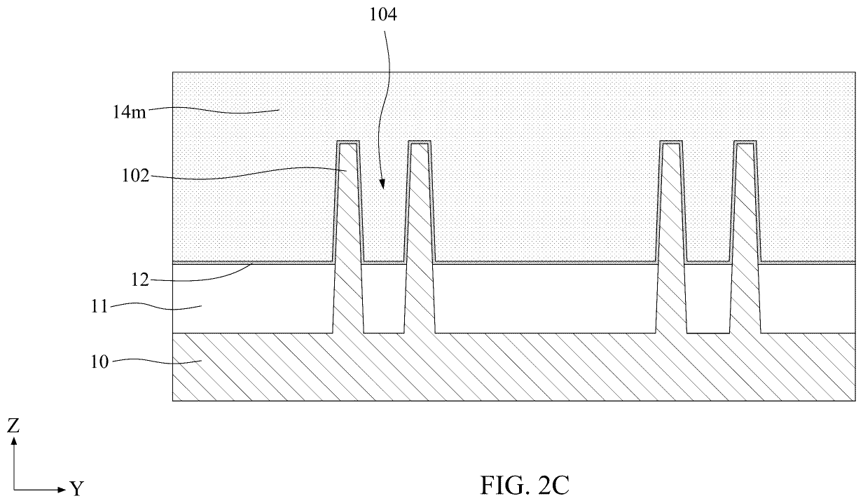

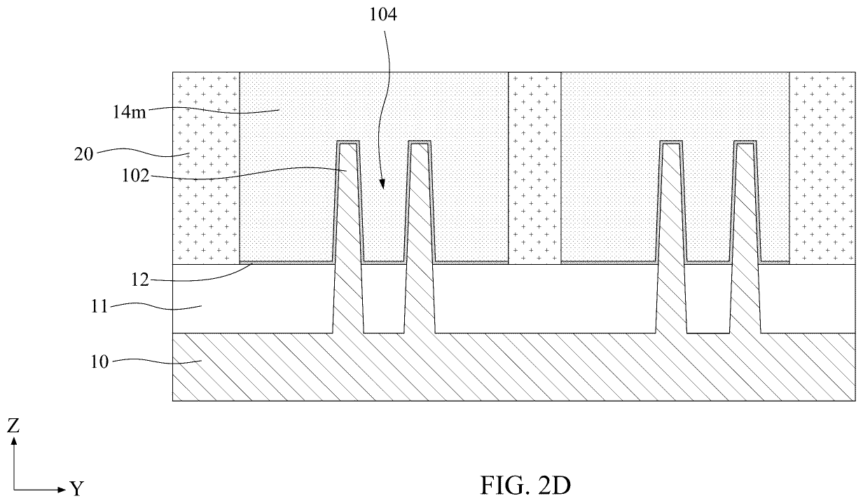

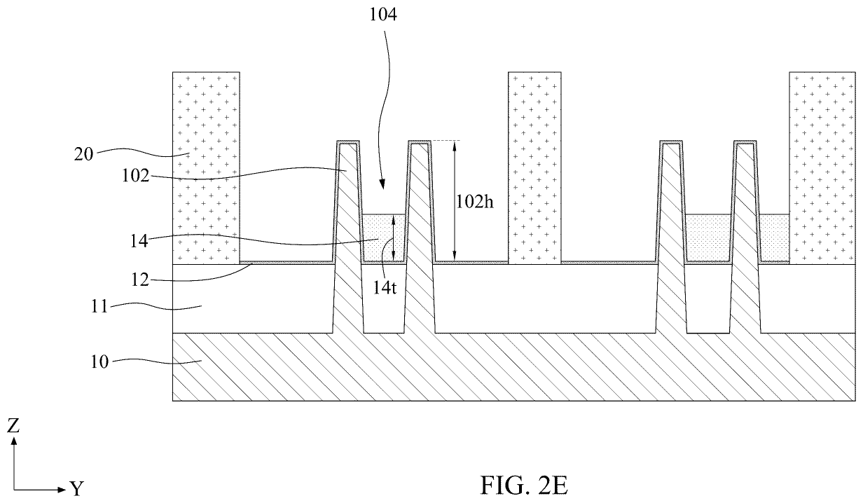

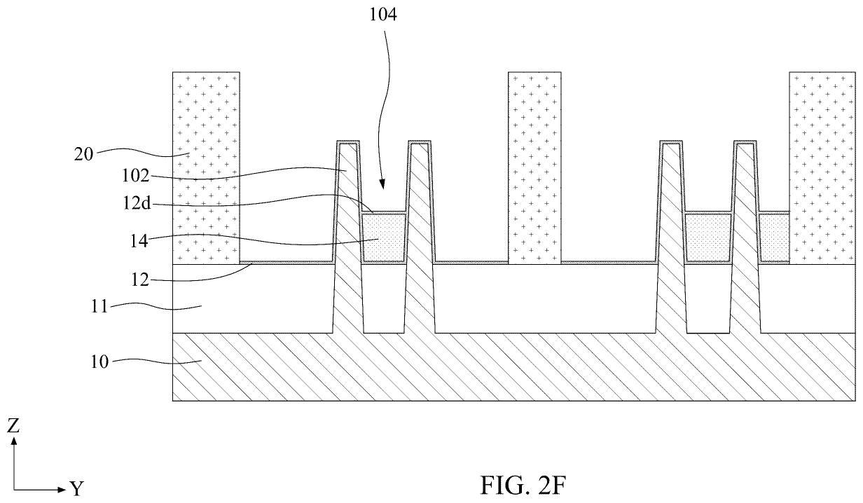

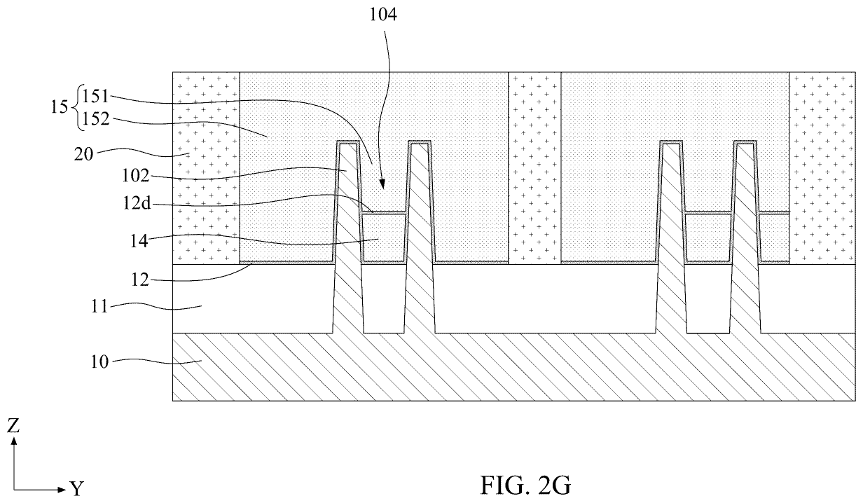

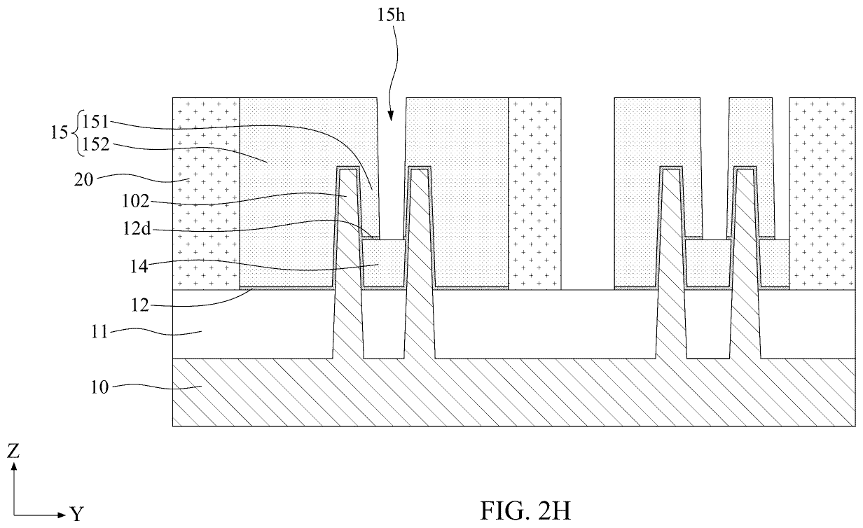

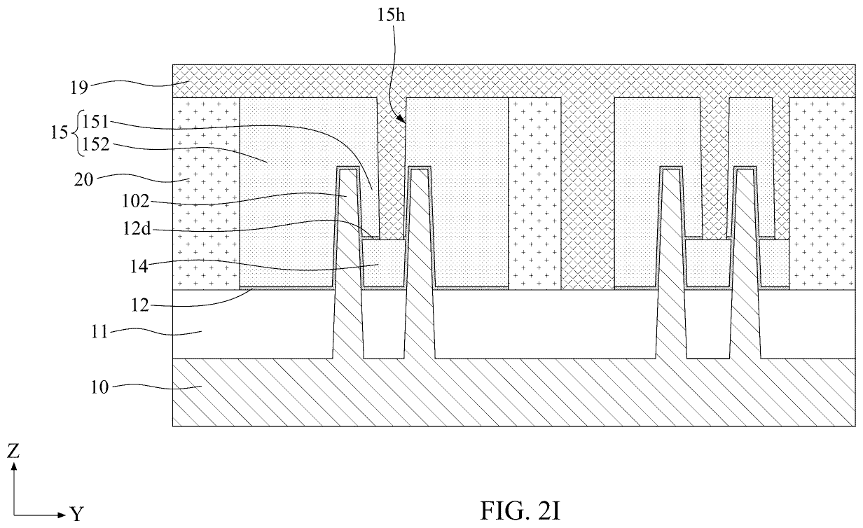

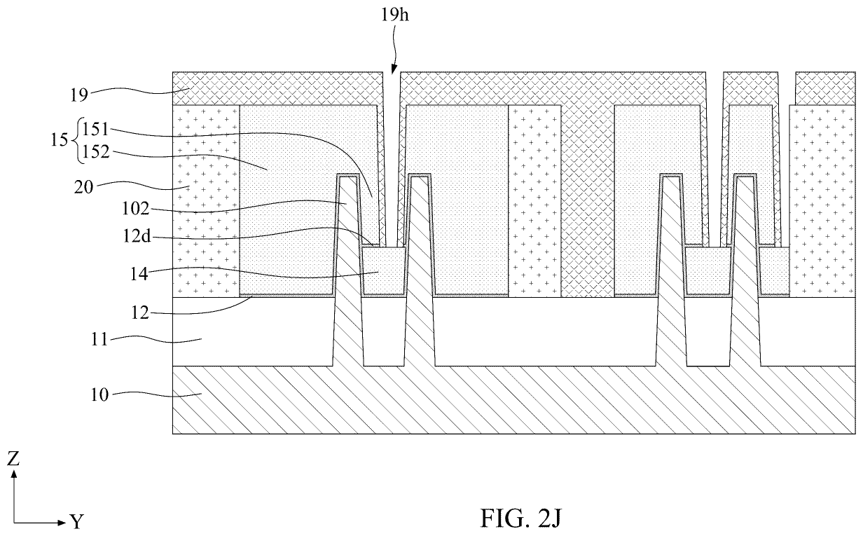

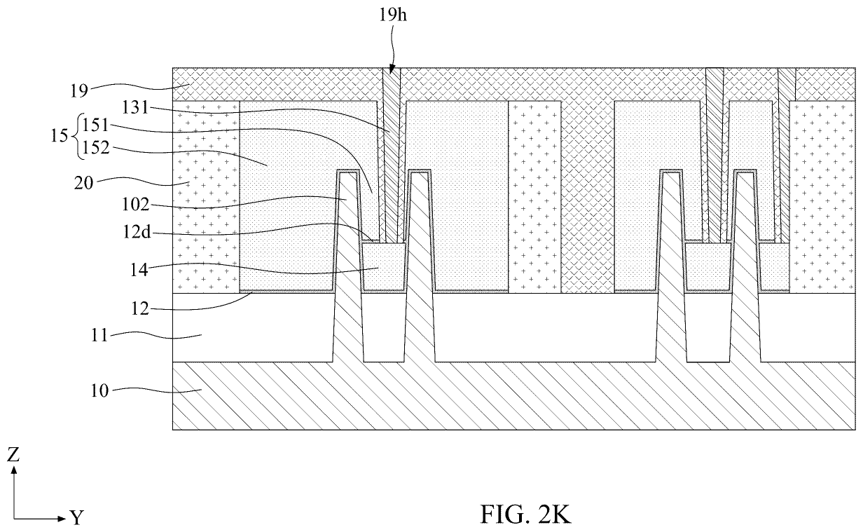

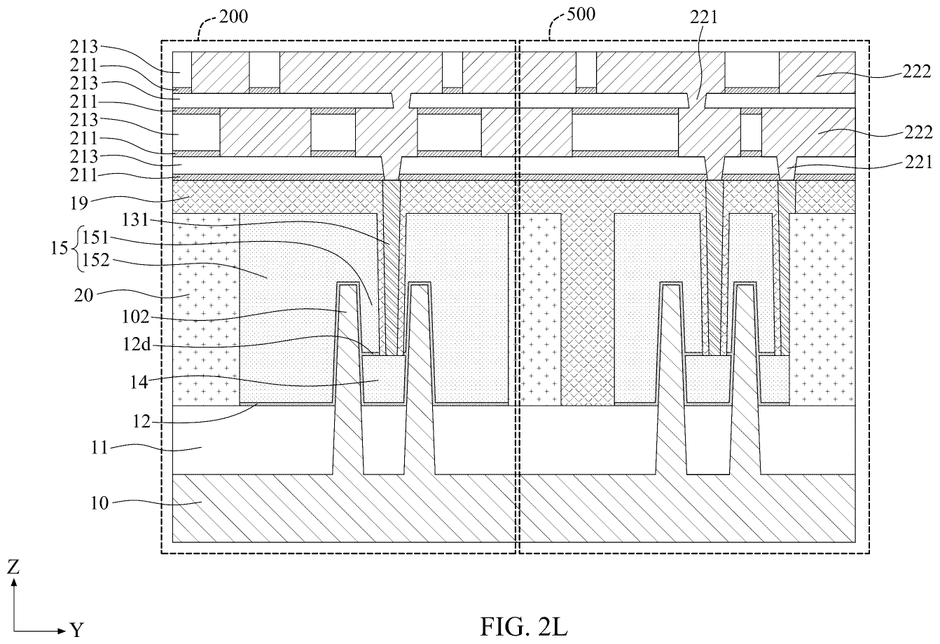

Method 100A is described below in conjunction with other figures, which illustrate various cross-sectional views of the semiconductor device 200 during intermediate steps of method 100A. FIGS. 2A, 2B, 2C, 2D, 2E, 2F, 2G, 2H, 2I, 2J, 2K, and 2L illustrate cross-sectional views of the semiconductor device 200.

The semiconductor device 200 may be an intermediate device fabricated during processing of an integrated circuit (IC), or a portion thereof, that may comprise static random-access memory (SRAM) and/or other logic circuits, passive components such as resistors, capacitors, and inductors, and active components such as p-type FETs (PFETs), n-type FETs (NFETs), fin-like FETs (FinFETs), gate all around (GAA), metal-oxide semiconductor field effect transistors (MOSFET), complementary metal-oxide semiconductor (CMOS) transistors, complementary FETs (CFETs), bipolar transistors, high voltage transistors, high frequency transistors, and/or other memory cells. The semiconductor device 200 can be a portion of a core region (often referred to as a logic region), a memory region (such as a static random access memory (SRAM) region), an analog region, a peripheral region (often referred to as an input/output (I/O) region), a dummy region, other suitable regions, or combinations thereof, of an integrated circuit (IC). In some embodiments, the semiconductor device 200 may be a portion of an IC chip, a system on chip (SoC), or portion thereof. The present disclosure is not limited to any particular number of devices or device regions, or to any particular device configurations. For example, though the semiconductor device 200 as illustrated is a three-dimensional FET device, the present disclosure may also provide embodiments for fabricating planar FET devices.

Referring to FIGS. 1 and 2A, at operation S101, method 100A provides a semiconductor device 200. The semiconductor device 200 includes a fin structure (or one or more fins (semiconductor fins)) 102 protruding from a substrate 10 and separated by an isolation structure 11. Substrate 10 may be a bulk substrate that includes silicon (Si). Alternatively or additionally, the bulk substrate includes another elementary semiconductor, a compound semiconductor, an alloy semiconductor, or combinations thereof. In some embodiments, substrate 10 includes n-type doped regions (for example, n-type wells) doped with n-type dopants, such as phosphorus, arsenic, other n-type dopant, or combinations thereof. In some embodiments, substrate 10 includes p-type doped regions (for example, p-type wells) doped with p-type dopants, such as boron, indium, other p-type dopants, or combinations thereof.

The fin structures (or one or more semiconductor fins) 102 are formed over substrate 10 and are oriented substantially parallel to one another. Each of semiconductor fins 102 has at least one channel region and at least one source region and one drain region defined along their length in the x-direction. In some embodiments, the fin structure 102 is a portion of substrate 10 (such as a portion of a material layer of substrate 10). In some other embodiments, the fin structure 102 may be defined in a material layer, such as one or more semiconductor material layers, overlying substrate 10. The semiconductor layers can include any suitable semiconductor materials, such as Si, germanium (Ge), silicon germanium (SiGe), other suitable semiconductor materials, or combinations thereof. The fin structure 102 is formed by any suitable process including various deposition, photolithography, and/or etching processes.

A gate trench 104 may be formed after the formation of the fin structure 102. The gate trench 104 may be surrounded by the fin structure 102. The gate trench 104 may be defined by the fin structure 102. The gate trench 104 may be between adjacent fins of the fin structure 102.

Isolation structure 11 is formed over substrate 10 and electrically isolates active device regions and/or passive device regions of device 200. Isolation structure 11 can be configured as different structures, such as a shallow trench isolation (STI) structure, a deep trench isolation (DTI) structure, a local oxidation of silicon (LOCOS) structure, or combinations thereof. In some embodiments, isolation structure 11 includes an isolation material, such as silicon oxide (SiO), silicon nitride (SiN), silicon oxynitride (SiON), other suitable isolation materials, or combinations thereof. Formation of isolation structure 11 includes deposition processes such as chemical vapor deposition (CVD), physical vapor deposition (PVD), atomic layer deposition (ALD), and a planarization process such as chemical mechanical planarization (CMP).

Referring to FIGS. 1 and 2B, at operation S103, method 100A forms a gate dielectric layer 12 over the fin structure 102 and/or the isolation structure 11. The gate dielectric layer 12 may be formed in the gate trench 104. In some embodiments, gate dielectric layer 12 includes a high-k dielectric material such as SiN, SiO, hafnium oxide (HfO), zirconium oxide, lanthanum oxide, titanium oxide, yttrium oxide, strontium titanite, other suitable metal-oxides, or combinations thereof; and may be formed by ALD and/or other suitable methods. In some embodiments, gate dielectric layer 12 has a thickness of about 1.5 nm to about 3 nm.

Referring to FIGS. 1 and 2C, at operation S105, method 100A forms a first gate material 14m in the gate trench 104. The first gate material 14m may be formed over the fin structure 102 and the gate dielectric layer 12. In some embodiments, the first gate material 14m may include polysilicon (or poly). The first gate material 14m may include a work function metal layer and a metal fill layer. The work function metal layer may be a p-type work function metal layer or an n-type work function metal layer. The p-type work function metal layer comprises a metal selected from, but not limited to, the group consisting of titanium nitride, tantalum nitride, ruthenium, molybdenum, tungsten, platinum, or combinations thereof. The n-type work function metal layer comprises a metal selected from, but not limited to, the group consisting of titanium, aluminum, tantalum carbide, tantalum carbide nitride, tantalum silicon nitride, or combinations thereof. The p-type or n-type work function metal layer may include a plurality of layers and may be deposited by CVD, PVD, and/or other suitable processes. In some embodiments, the metal fill layer may include aluminum, tungsten, cobalt, copper, and/or other suitable materials, and may be formed by CVD, PVD, plating, and/or other suitable processes. In some embodiments, the first gate material 14m may also include one or more other layers such as a barrier layer, a glue layer, and/or a hard mask layer.

Referring to FIGS. 1 and 2D, at operation S107, method 100A forms an insulation layer 20 to surround the first gate material 14m. The method 100A at operation S107 may further include removing a part of the first gate material 14m, with a mask, to form an opening; and forming an insulation material in the opening. The method 100A at operation S107 may further include performing a planarization process such as chemical mechanical planarization (CMP) to remove excess insulation material over the first gate material 14m and form the insulation layer 20 in the opening.

In some embodiments, insulation layer 20 includes an isolation material, such as silicon oxide (SiO), silicon nitride (SiN), silicon oxynitride (SiON), other suitable isolation materials, or combinations thereof. Formation of insulation layer 20 includes deposition processes such as chemical vapor deposition (CVD), physical vapor deposition (PVD), atomic layer deposition (ALD), and a planarization process such as chemical mechanical planarization (CMP).

Referring to FIGS. 1 and 2E, at operation S109, method 100A removes a portion of the first gate material 14m to form a first gate structure 14 in the gate trench 104. The first gate structure 14 may include a gate electrode and a portion of the gate dielectric layer 12. The first gate structure 14 may be surrounded by the fin structure (or the semiconductor fins) 102. In the z direction (or a direction substantially parallel to the fin structure 102), a thickness 14t of the first gate structure 14 may be smaller than a height 102h of a portion of the fin structure 102 protruding from the isolation structure 11. A portion of the first gate material 14m over the isolation structure 11 may be removed, while another portion of the first gate material 14m over the isolation structure 11 may remain. The method 100A may include removing the first gate material 14m to form a plurality of gate structures (the right side of FIG. 2E shows two gate structures). The gate structures may be at the same elevation. One of the gate structures may be formed in a gate trench and the other of the gate structures may be formed in a further gate trench separated from the gate trench by the fin structure 102. One of the gate structures may be surrounded by the fin structure 102 and the other of the gate structures may be in contact with the insulation layer 20.

Referring to FIGS. 1 and 2F, at operation S111, method 100A forms an oxide layer 12d above or on the first gate structure 14. The formation of the oxide layer 12d may be prior to the forming of a second gate structure in operation 113. The oxide layer 12d may be formed by oxidizing an exposed portion of the first gate structure 14. In some embodiments, the oxide layer 12d may be formed by a selective deposition process. Hence, the thickness of the gate dielectric layer 12 may be substantially the same as that of the oxide layer 12d. In some embodiments, the oxide layer 12d may have material the same or similar to the gate dielectric layer 12. In some embodiments, the oxide layer 12d may be referred to as a part of the gate dielectric layer 12.

Referring to FIGS. 1 and 2G, at operation S113, method 100A forms a second gate structure 15 above the first gate structure 14. The second gate structure 15 may be stacked over the first gate structure 14. The oxide layer 12d of the gate dielectric layer 12 may separate (or isolate) the first gate structure 14 from the second gate structure 15. The second gate structure 15 may have a portion 151 in the gate trench 104. The second gate structure 15 may have a portion 152 outside the gate trench 104. The portion 152 may surround the fin structure 102. The portion 152 of the second gate structure 15 may be between the fin structure 102 and the insulation layer 20. In some embodiments, the method 100A may further perform a CMP process to remove excess second gate material over the insulation layer 20. A top surface of the second gate structure 15 and a top surface of the insulation layer 20 may be substantially coplanar. In some embodiments, method 100A, at operation S113, may further form an upper gate structure above a plurality of lower gate structures (see the right side of FIG. 2G).

In some embodiments, the second gate structure 15 and the first gate structure 14 may include polysilicon (or poly). The second gate structure 15 and the first gate structure 14 may include a work function metal layer and a metal fill layer. The work function metal layer may be a p-type work function metal layer or an n-type work function metal layer. The p-type work function metal layer comprises a metal selected from, but not limited to, the group consisting of titanium nitride, tantalum nitride, ruthenium, molybdenum, tungsten, platinum, or combinations thereof. The n-type work function metal layer comprises a metal selected from, but not limited to, the group consisting of titanium, aluminum, tantalum carbide, tantalum carbide nitride, tantalum silicon nitride, or combinations thereof. The p-type or n-type work function metal layer may include a plurality of layers and may be deposited by CVD, PVD, and/or other suitable processes. In some embodiments, the metal fill layer may include aluminum, tungsten, cobalt, copper, and/or other suitable materials, and may be formed by CVD, PVD, plating, and/or other suitable processes. In some embodiments, the second gate structure 15 and the first gate structure 14 may also include one or more other layers such as a barrier layer, a glue layer, and/or a hard mask layer.

Referring to FIGS. 1 and 2H, at operation S115, method 100A forms a first opening 15h in the second gate structure 15 by anisotropic etching (e.g., dry etching). The formation of first opening 15h may be prior to forming a contact feature 131 in operation S121. The first opening 15h may penetrate the second gate structure 15. The first opening 15h may penetrate the gate dielectric layer 12 (e.g., oxide layer 12d). A portion of the first gate structure 14 may be exposed by the first opening 15h. The method 100A, at operation S115, may further form a plurality of openings in an upper gate structure to expose a plurality of lower gate structures (see the right side of FIG. 2H).

Referring to FIGS. 1 and 2I, at operation S117, method 100A may form a dielectric layer 19 in the first opening 15h. The dielectric layer 19 may be formed over the second gate structure 15. In some embodiments, the dielectric layer 19 may include material similar to or the same as the gate dielectric layer 12. Therefore, there may be no interface between the dielectric layer 19 and the gate dielectric layer 12 (e.g., the oxide layer 12d). The dielectric layer 19, the oxide layer 12d, and the gate dielectric layer 12 may be collectively referred to as an insulation layer (partially) surrounds the gate structures 14 and 15. The dielectric layer 19 may include an interlayer dielectric (ILD) layer. The ILD layer may include SiO, SiN, SiON, tetraethylorthosilicate (TEOS) formed oxide, undoped silicate glass, or doped silicon oxide such as borophosphosilicate glass (BPSG), fused silica glass (FSG), phosphosilicate glass (PSG), boron doped silicon glass (BSG), low-k (K<3.9) dielectric material, other suitable dielectric materials, or combinations thereof. Therefore, there may be an interface between the dielectric layer 19 and the gate dielectric layer 12 (e.g., the oxide layer 12d).

Referring to FIGS. 1 and 2J, at operation S119, method 100A forms a second opening 19h in the dielectric layer 19 by anisotropic etching (e.g., dry etching). The second opening 19h may be substantially aligned with the first opening 15h. A diameter of the second opening 19h may be smaller than that of the first opening 15h. The second opening 19h may penetrate the dielectric layer 19. The second opening 19h may penetrate the second gate structure 15 and/or the gate dielectric layer 12 (e.g., oxide layer 12d). A portion of the first gate structure 14 may be exposed by the second opening 19h. The method 100A, at operation S119, may further form a plurality of openings in the dielectric layer 19 to expose a plurality of lower gate structures (see the right side of FIG. 2J).

Referring to FIGS. 1 and 2K, at operation S121, method 100A forms a contact feature 131 in the second opening 19h to connect the first gate structure 14, wherein the contact feature 131 penetrates the second gate structure 15. The contact feature 131 is surrounded by the second gate structure 15. The contact feature 131 is isolated or separated from the second gate structure 15 by the dielectric layer 19. The contact feature 131 may penetrate the dielectric layer 19 and/or the gate dielectric layer 12 (e.g., the oxide layer 12d). The diameter of the contact feature 131 may be determined by the second opening 19h. The contact feature 131 may have a tapered profile. In some embodiments, the contact feature 131 may have a uniform width. The contact feature 131 may include a conductive material and is formed by a suitable deposition process, such as CVD, PVD, ALD, and/or other suitable processes. A CMP process may be performed to remove any excess material from the contact feature 131 and planarize the top surface of the semiconductor device 200.

In some embodiments, the method 100A, at operation S121, may form a plurality of contact features penetrating an upper gate structure to connect a plurality of lower gate structures (see the right side of FIG. 2K).

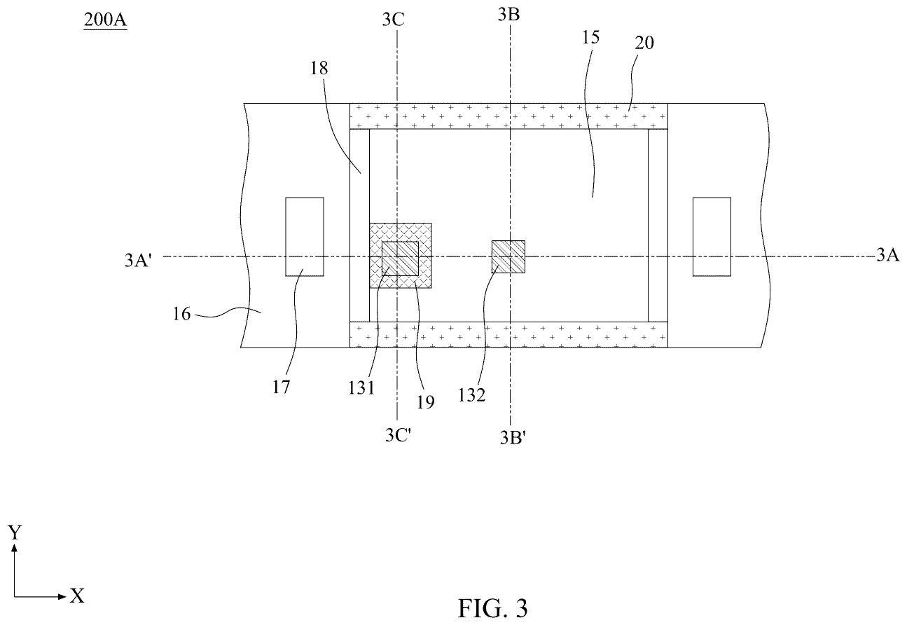

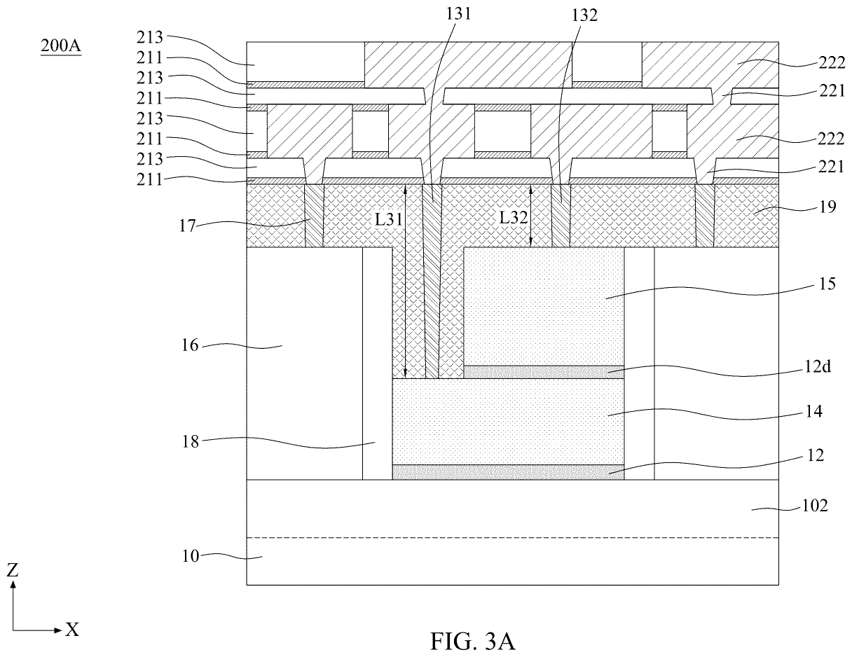

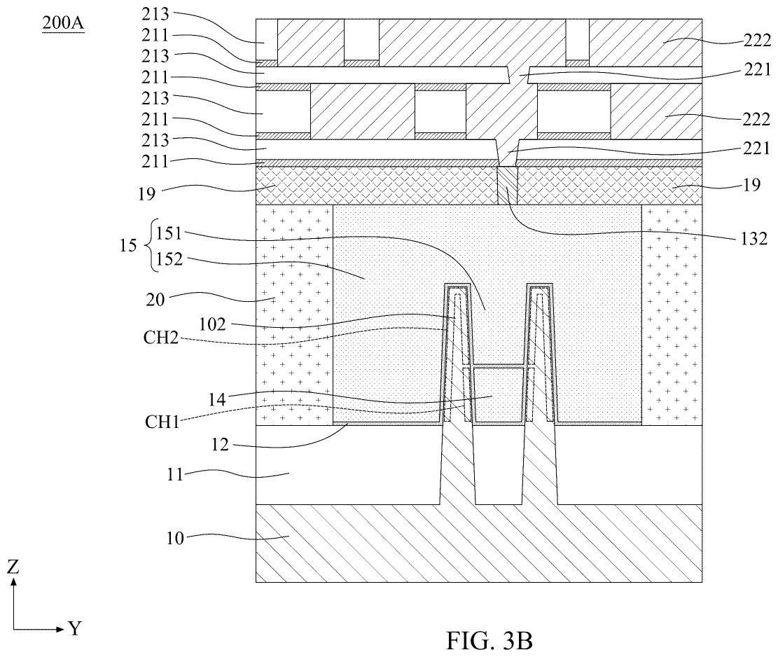

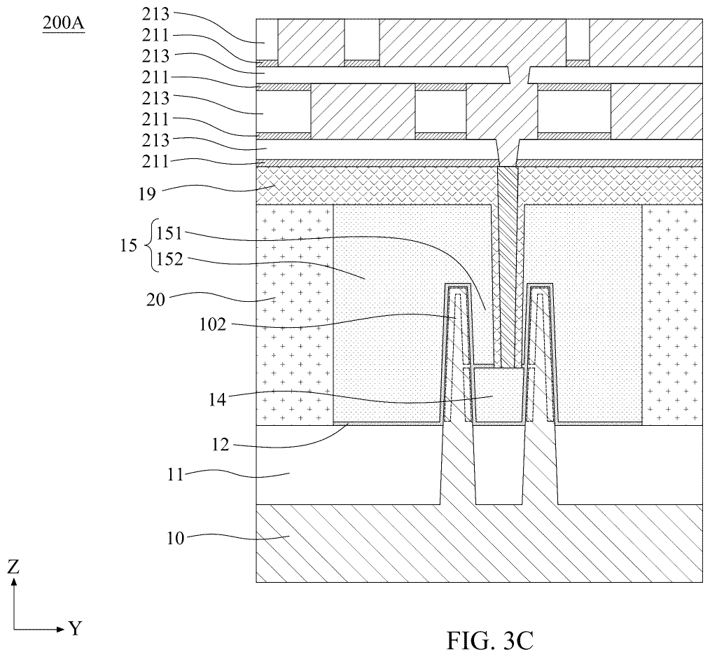

In some embodiments, the method 100A, at operation S121, may form a further contact feature over the second gate structure 15 (see contact feature 132 in FIG. 3A). Along the z direction, the length of the contact feature 131 is greater than the length of the contact feature 132. The contact feature 131 and the contact feature 132 may be formed in the same process steps. The contact features 131 and 132 with different lengths fulfill the electrical connection between the metal lines (or vias) and the stacked gate structures 14 and 15. The first gate structure 14 and the second gate structure 15 can be configured to receive different electrical signals through, e.g., the contact features 131 and 132.

Referring to FIGS. 1 and 2L, at operation S123, method 100A performs further processing to complete the fabrication of semiconductor device 200. For example, it may form various other contacts/vias 221, metal lines 222, as well as other multilayer interconnect features such as ILD layers 213 and etch stop layers (ESLs) 211 over semiconductor device 200, configured to connect the various features to form a functional circuit that may include the semiconductor device 200. The method 100A, at operation S123, may form a first via (e.g., 221) connecting to the contact feature 131 and a second via (e.g., 221) connecting to the contact feature 132.

Contact feature 131 may be connected to one of the vias 221. In some embodiments, further contact features may be connected to the vias 221 (see the right side of FIG. 2L).

In some embodiments, method 100A performs further processing to complete the fabrication of semiconductor device 500 (see the right side of FIG. 2L).

The present disclosure provides a semiconductor device (e.g., 200 or 500) and the fabrication thereof. The semiconductor device 200 may include the stacked gate structures 14 and 15 and the fin structure 102. The gate structures 14 and 15 may be included in MOSFET, CMOS transistors, complementary FETs (CFETs), GAA, or FinFETs. The gate structures 14 and 15 may be configured to control (or generate) individual channels in the fin structure 102. Each of the gate structures 14 and 15 and a respective channel may collectively form a part of one transistor. If at least one of the channels is generated, the semiconductor device 200 would be turned on; only if none of the channels is generated, the semiconductor device 200 would be turned off. That is, the semiconductor device 200 functions as multiple transistors electrically connected in parallel but has a relatively small area. The design layout flexibility can be enhanced, enabling increased functional density. Semiconductor device 200 may be referred to as a dual-gate transistor. Semiconductor device 500 may be referred to as a multiple-gate transistor.

FIG. 3 is a top view illustrating a semiconductor device 200A in accordance with some embodiments of the present disclosure. FIG. 3A is a cross-sectional view illustrating the semiconductor device 200 in accordance with some embodiments of the present disclosure. FIG. 3B is a cross-sectional view illustrating the semiconductor device 200 in accordance with some embodiments of the present disclosure. FIG. 3C is a cross-sectional view illustrating the semiconductor device 200A in accordance with some embodiments of the present disclosure. The structure of the semiconductor device 200A is similar to the structure of the semiconductor device 200 in FIG. 2L. In some embodiments, the semiconductor device 200A may include the substrate 10, the fin structure (or the semiconductor fins) 102, the isolation structure 11, the gate dielectric layer 12, the contact feature 131, the gate structures 14 and 15, the dielectric layer 19, the insulation layer 20, the ESLs 211, the ILD layers 213, the contacts/vias 221, and metal lines 222. The descriptions of these semiconductor components can be referenced in relation to FIGS. 2A-2L. Therefore, some detailed descriptions may refer to corresponding preceding paragraphs and are not repeated hereinafter for conciseness.

As shown in FIG. 3, a portion of the dielectric layer 19 above the second gate structure 15 is omitted to provide a clearer view of the semiconductor components that are typically covered by this layer. Another portion of the dielectric layer 19 at the same elevation with the second gate structure 15 is shown in FIG. 3. The contact feature 131 may be surrounded by the dielectric layer 19.

The semiconductor device 200A includes S/D features 16. S/D features 16 include semiconductor material such as silicon germanium (SiGe), silicon phosphide (SiP), or silicon carbide (SiC). An epitaxy process can implement CVD deposition techniques (for example, vapor-phase epitaxy (VPE), ultra-high vacuum CVD (UHV-CVD), low pressure CVD (LPCVD), and/or plasma-enhanced CVD (PECVD)), molecular beam epitaxy (MBE), other suitable selective epitaxial growth (SEG) processes, or combinations thereof.

The semiconductor device 200A includes S/D contacts 17 above the S/D features 16. The S/D contacts 17 may include a conductive material and are formed by a suitable deposition process, such as CVD, PVD, ALD, and/or other suitable processes.

The semiconductor device 200A includes a gate spacer 18 between the second gate structure 15 and the S/D features 16. The gate spacer 18 may isolate or separate the second gate structure 15 from the S/D features 16. The gate spacer 18 may be in contact with the insulation layer 20. The gate spacer 18 may include silicon, oxygen, carbon, nitrogen, other suitable materials, or combinations thereof (for example, SiO, SiN, SiON, or silicon carbide (SiC), silicon carbon nitride (SiCN), silicon oxycarbonitride (SiOCN)) are formed by a suitable process such as deposition, etching, and/or other suitable processes.

The semiconductor device 200A includes a contact feature 132 disposed over the second gate structure 15, and the contact feature 131 surrounded by the second gate structure 15. The contact feature 131 may be adjacent to the gate spacers 18. The location of the contact feature 131 and the contact feature 132 is varied based on the design layout.

FIG. 3A is a cross-sectional view along the line 3A-3A′ in FIG. 3. As shown in FIG. 3A, the contact feature 131 is connected to the first gate structure 14, and the contact feature 132 is connected to the second gate structure 15. A first length L31 of the contact feature 131 is greater than a second length L32 of the contact feature L32. The contact feature 131 may extend along a lateral surface of the second gate structure 15. The contact feature 131 and the contact feature 132 may have a tapered profile. In some embodiments, the contact feature 131 and the contact feature 132 may have a uniform width.

The S/D features 16 may be epitaxially grown over the S/D regions of the fin structure 102. The gate spacer 18 may interface with the first gate structure 14 and the second gate structure 15. The S/D contacts 17 may have a tapered profile. In some embodiments, the S/D contacts 17 may have a uniform width. The length of the S/D contacts 17 may be shorter than the first length L31 but substantially the same as the second length L32.

FIG. 3B is a cross-sectional view along the line 3B-3B′ in FIG. 3. FIG. 3C is a cross-sectional view along the line 3C-3C′ in FIG. 3.

Referring to FIG. 3B, the contact feature 132 may be connected to the second gate structure 15. The contact feature 132 may be embedded in the dielectric layer 19. The contact feature 132 is spaced apart from the first gate structure 14.

As shown in FIG. 3C, the contact feature 131 may be connected to the first gate structure 14. The contact feature 131 is spaced apart from the second gate structure 15. The contact feature 131 may be embedded in the dielectric layer 19. In some embodiments, the dielectric layer 19 may be referred to as a part of the gate dielectric layer 12 when they are made of the same or a similar material. The second gate structure 15 may include a part of the dielectric layer 19 as its gate dielectric layer. Hence, in the present disclosure, the contact feature 131 may penetrate the second gate structure 15.

Referring back to FIG. 3B, the first gate structure 14 is configured to control a first channel (or first channel region) CH1 in the fin structure 102, and the second gate structure 15 is configured to control a second channel (or second channel region) CH2 in the fin structure 102. The first channel CH1 may extend along the dielectric layer 12. The second channel CH2 may extend along the dielectric layer 12. The first channel CH1 is different from the second channel CH2 in terms of the location.

The first channel CH1 may be generated if a voltage applied to the first gate structure 14 exceeds a first threshold voltage of the first gate structure 14 and the S/D feature 16. The second channel CH2 may be generated if a voltage applied to the second gate structure 15 exceeds a second threshold voltage of the second gate structure 15 and the S/D feature 16. The first gate structure 14, the first channel CH1, and the S/D features 16 may form a first transistor; and the second gate structure 15, the second channel CH2, and the S/D features 16 may form a second transistor electrically connected to the first transistor in parallel. The first threshold voltage may be different from the second threshold voltage. The width of the first channel CH1 may be different from that of the second channel CH2. Thus, the saturation current of the first transistor may be different from that of the second transistor. In some embodiments, the second transistor may have higher driving capacity than the first transistor. This difference may influence the electrical characteristics when the semiconductor device 200A is applied in an analog circuit, but can be ignored when the semiconductor device 200A is integrated into a logic circuit.

The semiconductor device 200A includes the stacked gate structures 14 and 15, the fin structure 102, and the S/D features 16. The first gate structure 14 and the second gate structure 15 may be configured to receive electrical signals through the longer contact feature 131 and the shorter contact feature 132, respectively. The first gate structure 14 and the second gate structure 15 can be configured to control (or generate) individual channels (e.g., CH1 and CH2) between the S/D features 16. In some embodiments, the semiconductor device 200A may be a plurality of transistors electrically connected in parallel (hereinafter referred to as “parallel transistors”) of a logic gate. If at least one of the parallel transistors is turned on, the semiconductor device 200A would be turned on; only if none of the parallel transistors is generated, the semiconductor device 200A would be turned off. Semiconductor device 200A may be referred to as a dual-gate transistor. That is, the semiconductor device 200A functions as multiple transistors electrically connected in parallel but has a relatively small area. The design layout flexibility can be enhanced, enabling increased functional density.

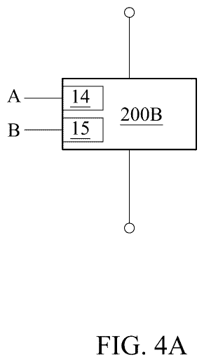

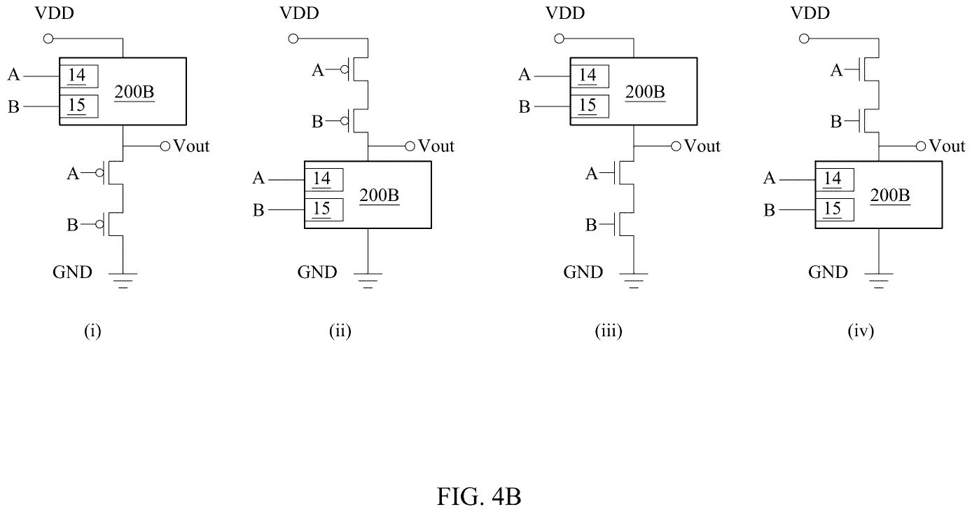

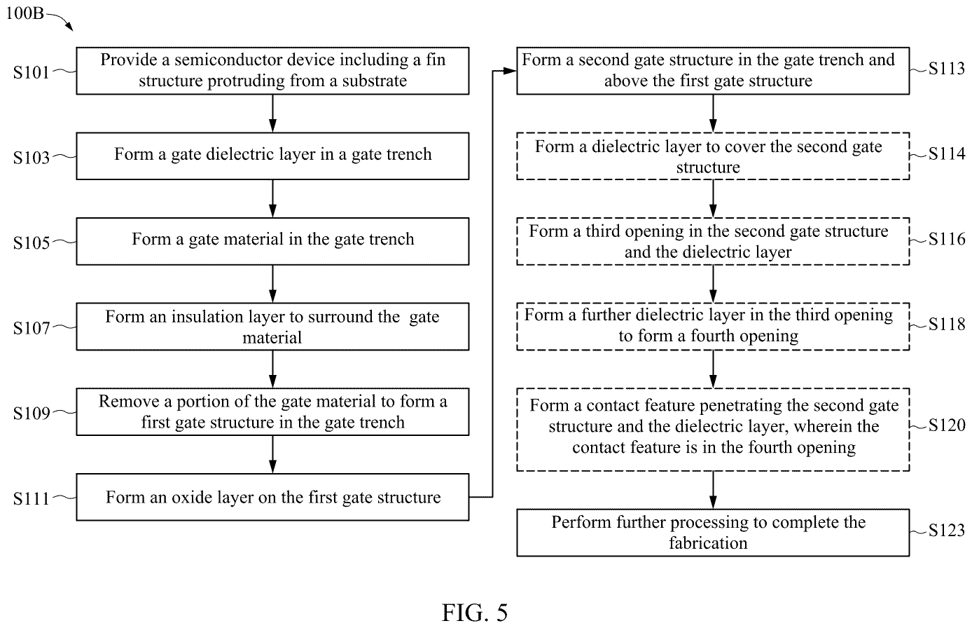

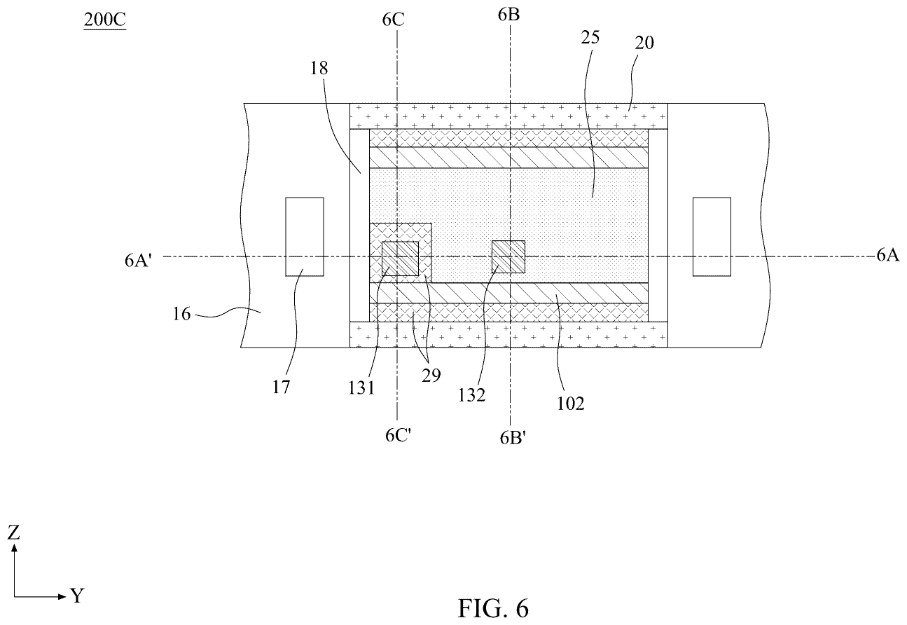

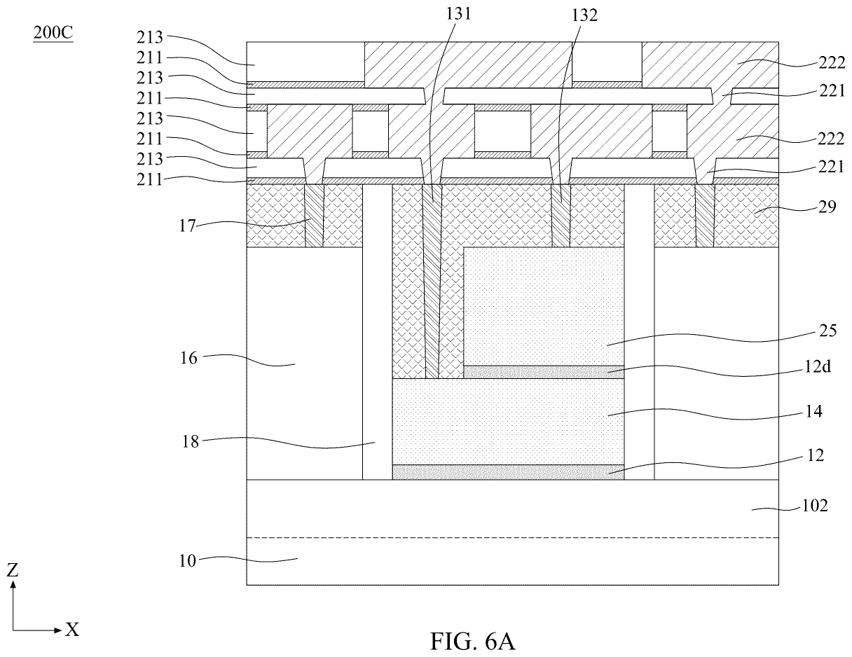

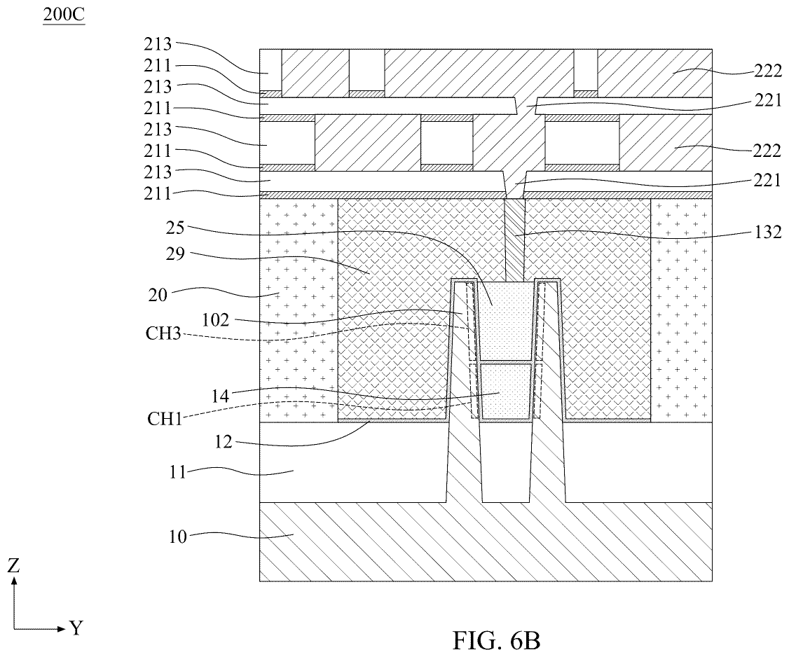

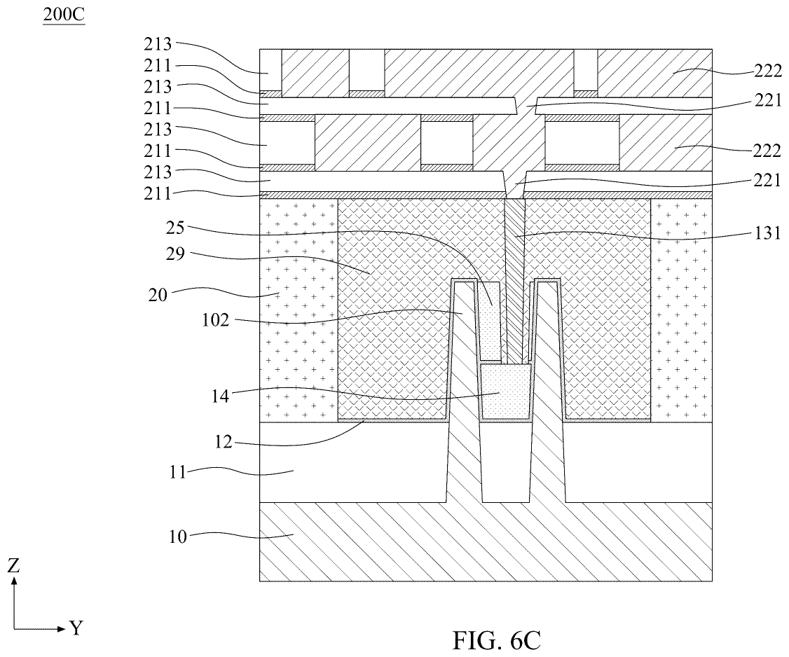

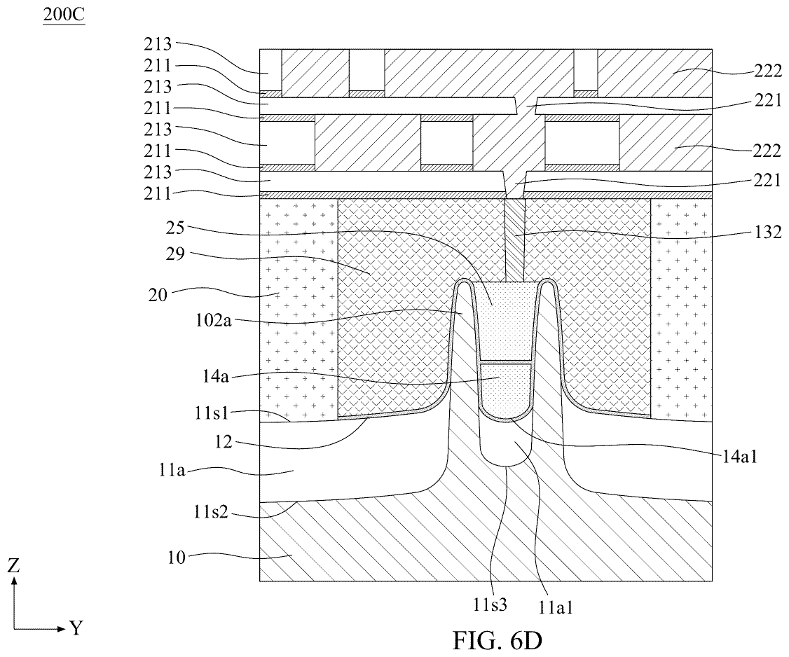

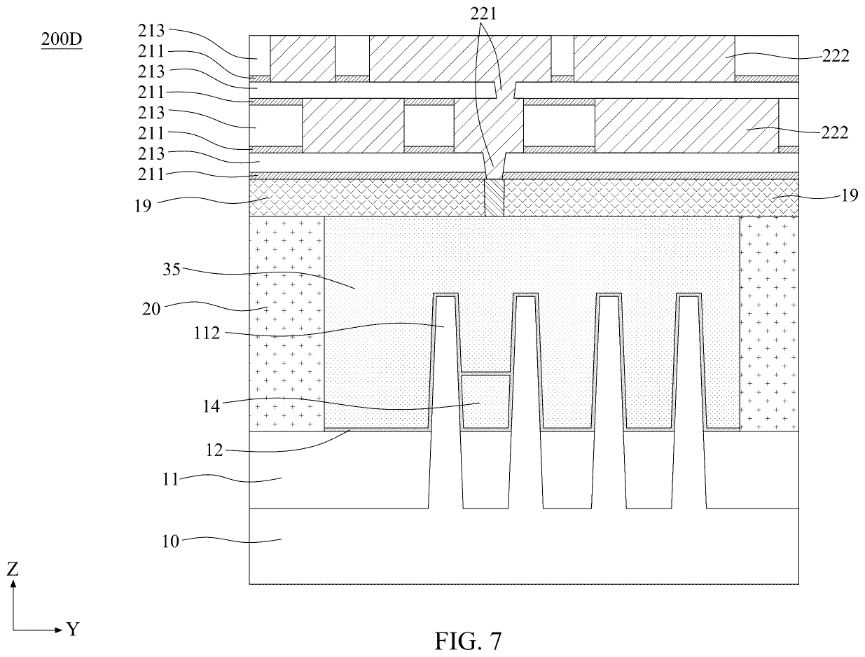

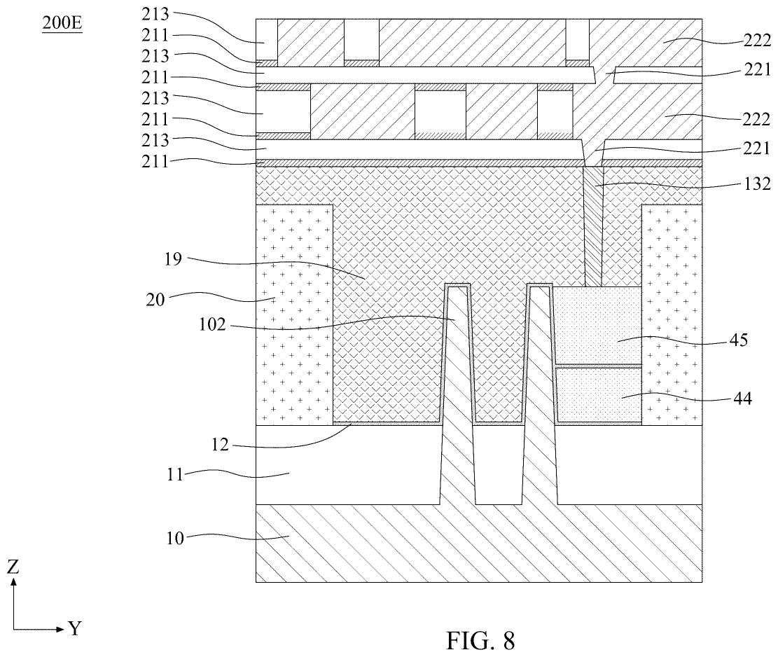

FIG. 4A is a schematic diagram illustrating a semiconductor device (or dual-gate transistor) 200B in accordance with some embodiments of the present disclosure. The semiconductor device 200B may be the semiconductor device 200 in FIG. 2L, the semiconductor device 200A in FIGS. 3-3C, the semiconductor device 200C in FIGS. 6-6C, the semiconductor device 200D in FIG. 7, and the semiconductor device 200E in FIG. 8.

The first gate structure 14 is one of the dual gates of the semiconductor device 200B, and the second gate structure 15 is the other of the dual gates. The first gate structure 14 may be configured to receive a signal A, and the second gate structure 15 may be configured to receive a signal B, independent of the signal A. The semiconductor device 200B may be a dual-gate n-type transistor. If signal A and signal B are 0 (“logic low”), the semiconductor device 200B is off. If at least one of signal A and signal B is 1 (“logic high”), the semiconductor device 200B is on. The semiconductor device 200B may be a dual-gate p-type transistor. If signal A and signal B are 1 (“logic high”), the semiconductor device 200B is off. If at least one of signal A and signal B is 0 (“logic low”), the semiconductor device 200B is on.

The semiconductor device (or the dual-gate transistor) 200B may be connected to transistors to form logic gates (e.g., OR gate, NOR gate, AND gate, or NAND gate). FIG. 4B illustrates circuit diagrams of a device (e.g., OR gate, NOR gate, AND gate, or NAND gate) including the semiconductor device 200B in accordance with some embodiments of the present disclosure.

As shown in (i) of FIG. 4B, the semiconductor device 200B may be a dual-gate n-type transistor having a first terminal connected to a voltage supply VDD, and a second terminal connected to a plurality of p-type transistors, which are connected in series (hereinafter referred to as “series p-type transistors”). The series p-type transistors are connected to the ground GND. The truth table of the device (OR gate) in (i) is presented in Table 1:

TABLE 1

| A | B | Vout |
|---|---|---|
| 0 | 0 | 0 |
| 0 | 1 | 1 |
| 1 | 0 | 1 |
| 1 | 1 | 1 |

As shown in (ii) of FIG. 4B, the semiconductor device 200B may be a dual-gate n-type transistor having a first terminal connected to the ground GND, and a second terminal connected to series p-type transistors, which are connected to the voltage supply VDD. The truth table of the device (NOR gate) in (ii) is presented in Table 2:

TABLE 2

| A | B | Vout |
|---|---|---|
| 0 | 0 | 1 |
| 0 | 1 | 0 |
| 1 | 0 | 0 |
| 1 | 1 | 0 |

As shown in (iii) of FIG. 4B, the semiconductor device 200B may be a dual-gate p-type transistor having a first terminal connected to a voltage supply VDD, and a second terminal connected to a plurality of n-type transistors, which are connected in series (hereinafter referred to as “series n-type transistors”). The series n-type transistors are connected to the ground GND. The truth table of the device (NAND gate) in (i) is presented in Table 1:

TABLE 3

| A | B | Vout |
|---|---|---|
| 0 | 0 | 1 |
| 0 | 1 | 1 |
| 1 | 0 | 1 |
| 1 | 1 | 0 |

As shown in (iv) of FIG. 4B, the semiconductor device 200B may be a dual-gate p-type transistor having a first terminal connected to the ground GND, and a second terminal connected to series n-type transistors, which are connected to the voltage supply VDD. The truth table of the device (AND gate) in (ii) is presented in Table 4:

TABLE 4

| A | B | Vout |
|---|---|---|
| 0 | 0 | 0 |
| 0 | 1 | 0 |
| 1 | 0 | 0 |
| 1 | 1 | 1 |

In some cases, building logic gates by incorporating multiple transistors electrically connected in parallel would occupy a relatively large area, thereby limiting design layout flexibility and reducing functional density. In the present disclosure, the semiconductor device (or dual-gate transistor) 200B (or 200, 200A, 200C, 200D, 200E) having function of parallel transistors, occupies a relatively small area. The design layout flexibility can be enhanced, enabling increased functional density.

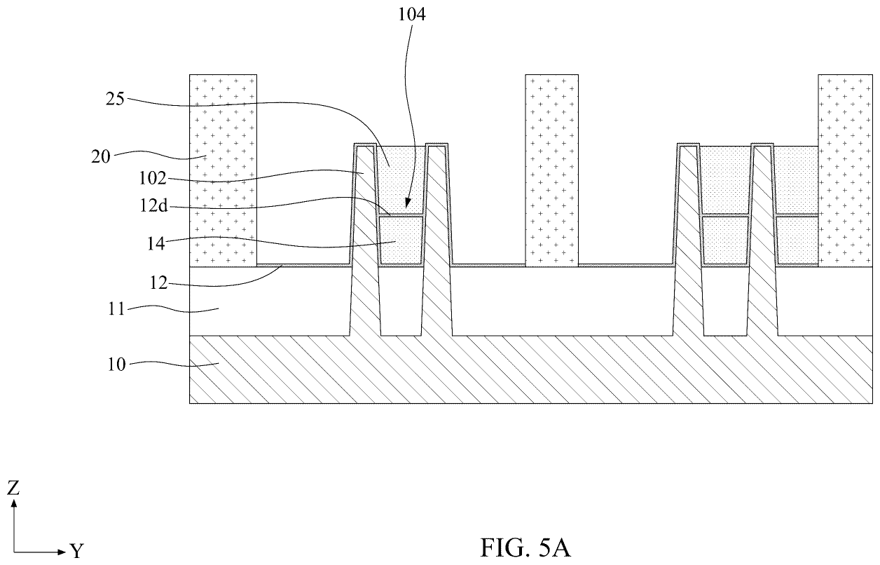

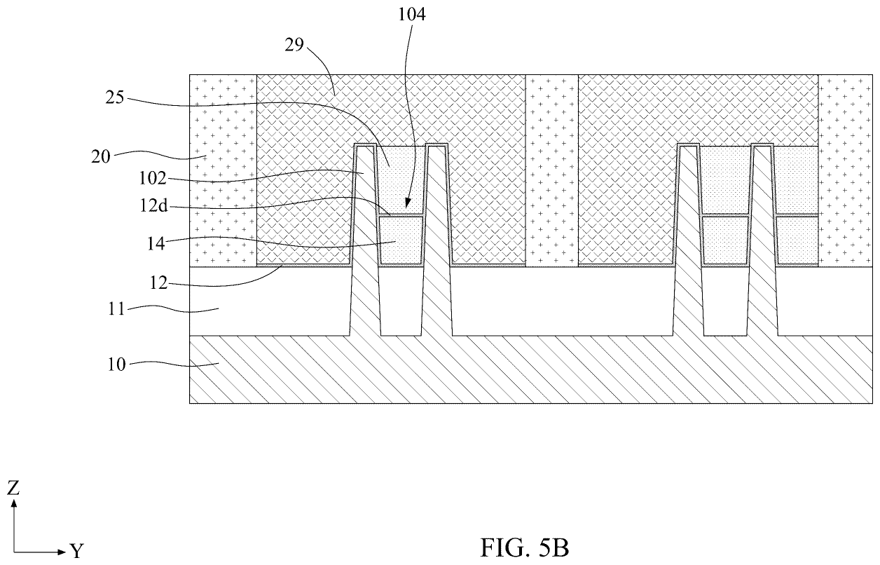

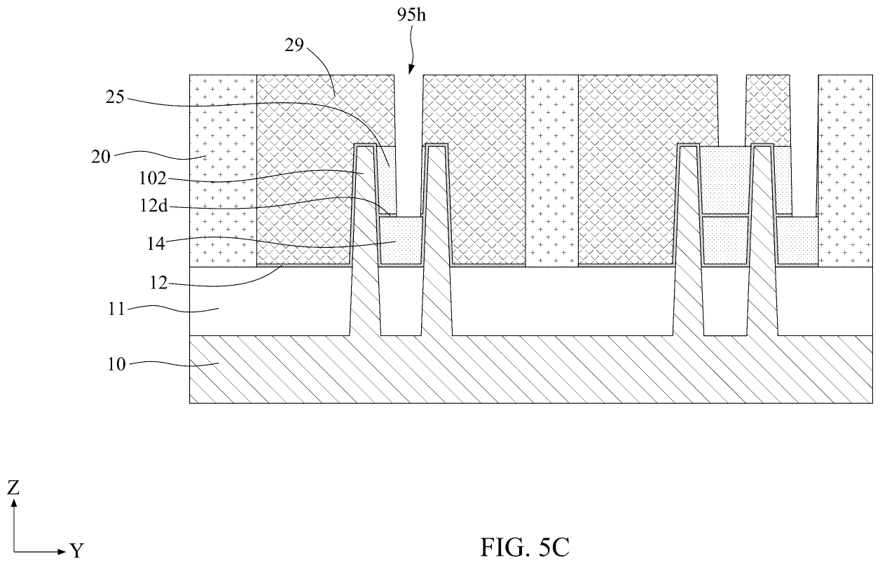

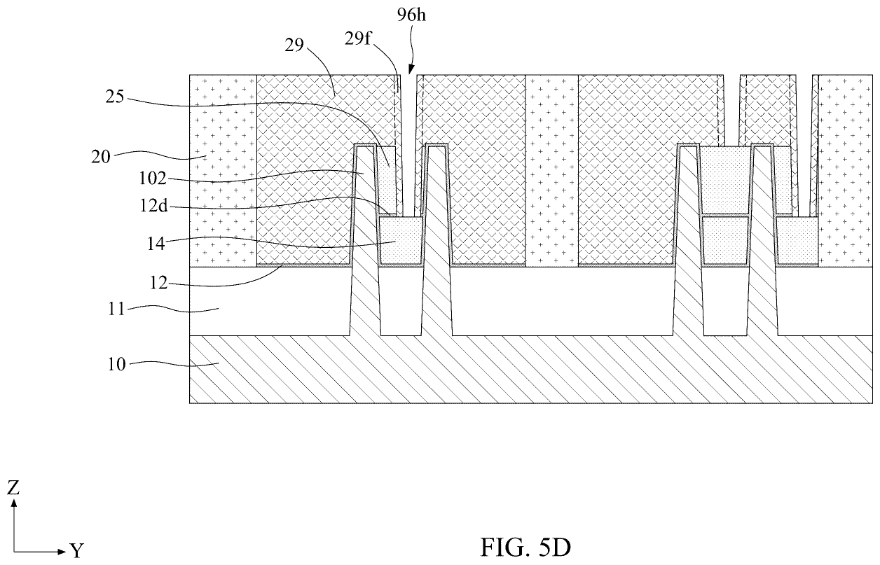

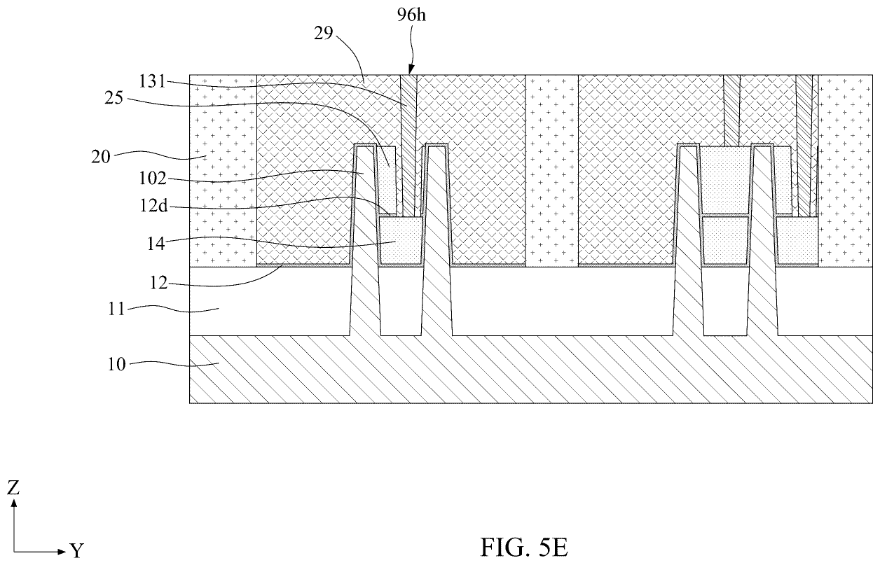

FIG. 5 illustrates a flow chart of a method 100B for forming a semiconductor device (e.g., 200C) in accordance with some other embodiments of the present disclosure. Method 100B is merely an example and is not intended to limit the present disclosure beyond what is explicitly recited in the claims. Additional operations can be performed before, during, and after operations of method 100B, and some operations described can be replaced, eliminated, or moved around for additional embodiments of the method. Method 100B includes steps similar to those of method 100A. Method 100B also includes different steps, or a different order of steps, than those in method 100A. For example, operations S101-S113, and S123 of method 100B correspond to operations S101-S113, and S123 of method 100A, respectively. Operations S114, S116, S118, and S120 of method 100B differ from operations S115, S117. S119, and S121 of method 100B. Operations S113, S114, S116, S118, and S120 of method 100B in FIG. 5 are described below in conjunction with other figures, which illustrate various cross-sectional views of device 200C during intermediate steps of method 100B. FIGS. 5A, 5B, 5C, 5D, and 5E illustrate cross-sectional views of the semiconductor device 200C.

Referring to FIGS. 1 and 5A, at operation S113, method 100B performs an etch process to form a second gate structure 25. The second gate structure 25 may be stacked over the first gate structure 14. The oxide layer 12d of the gate dielectric layer 12 may separate (or isolate) the first gate structure 14 from the second gate structure 25. The second gate structure 25 may be formed by a selective etch process. The second gate structure 25 is in the gate trench 104. The second gate structure 25 is surrounded by the fin structure 102. The second gate structure 25 is not outside the gate trench 104. The top surface of the second gate structure 25 is lower than the top surface of the isolation layer 20 with respect to the substrate 10.

The material of the second gate structure 25 may be similar to that of the second gate structure 15 in FIG. 2G.

In some embodiments, the method 100B, at operation S113, forms a plurality of upper gate structures above a plurality of lower gate structures (see the right side of FIG. 5A).

Referring to FIGS. 1 and 5B, at operation S114, method 100B forms a dielectric layer 29 to cover the second gate structure 25. The dielectric layer 29 may surround the fin structure 102. In some embodiments, the method 100B may further perform a CMP process to remove excess dielectric layer 29 over the insulation layer 20. A top surface of the dielectric layer 29 and a top surface of the insulation layer 20 may be substantially coplanar.

In some embodiments, the dielectric layer 29 may include material similar to or the same as that of the gate dielectric layer 12. Therefore, there may be no interface between the dielectric layer 29 and the gate dielectric layer 12 (e.g., the oxide layer 12d). The dielectric layer 29 may include an interlayer dielectric (ILD) layer. The ILD layer may include SiO, SiN, SiON, tetraethylorthosilicate (TEOS) formed oxide, undoped silicate glass, or doped silicon oxide such as borophosphosilicate glass (BPSG), fused silica glass (FSG), phosphosilicate glass (PSG), boron doped silicon glass (BSG), low-k (K<3.9) dielectric material, other suitable dielectric materials, or combinations thereof. Therefore, there may be an interface between the dielectric layer 19 and the gate dielectric layer 12 (e.g., the oxide layer 12d).

Referring to FIGS. 1 and 5C, at operation S116, method 100B forms a third opening 95h in the second gate structure 25 and the dielectric layer 29 by anisotropic etching (e.g., dry etching). The third opening 95h may penetrate the second gate structure 25. The third opening 95h may penetrate the gate dielectric layer 12 (e.g., oxide layer 12d). A portion of the first gate structure 14 may be exposed by the third opening 95h. The method 100B, at operation S116, may further form a plurality of openings in the upper gate structures to expose a plurality of lower gate structures (see the right side of FIG. 5C).

Referring to FIGS. 5 and 5D, at operation S118, method 100B may form a further dielectric layer 29f in the third opening 95h to form a fourth opening 96h. In some embodiments, the dielectric layer 29f may include material similar to or the same as that of the dielectric layer 29. The dielectric layer 29f may be a part of the dielectric layer 29.

The fourth opening 96h may be substantially aligned with the third opening 95h. A diameter of the fourth opening 96h may be smaller than that of the third opening 95h. The fourth opening 96h may penetrate the dielectric layer 29. The fourth opening 96h may penetrate the second gate structure 25 and/or the gate dielectric layer 12 (e.g., oxide layer 12d). A portion of the first gate structure 14 may be exposed by the fourth opening 96h. The method 100B, at operation S118, may further form a plurality of openings in the dielectric layer 29 to expose a plurality of lower gate structures (see the right side of FIG. 5D).

Referring to FIGS. 5 and 5E, at operation S120, method 100B forms a contact feature 131 in the fourth opening 96h to connect the first gate structure 14, wherein the contact feature 131 penetrates the second gate structure 25 and the dielectric layer 29. The contact feature 131 is surrounded by the second gate structure 25 and the dielectric layer 29. The contact feature 131 is isolated or separated from the second gate structure 25 by the dielectric layer 29. The contact feature 131 may penetrate the gate dielectric layer 12 (e.g., the oxide layer 12d). The diameter of the contact feature 131 may be determined by the fourth opening 96h. The contact feature 131 may have a tapered profile. In some embodiments, the contact feature 131 may have a uniform width. The contact feature 131 may include a conductive material and is formed by a suitable deposition process, such as CVD, PVD, ALD, and/or other suitable processes. A CMP process may be performed to remove any excess material from the contact feature 131 and planarize the top surface of the semiconductor device 200C.

In some embodiments, the method 100B, at operation S120, may form a plurality of contact features penetrating an upper gate structure to connect a plurality of lower gate structures (see the right side of FIG. 5E).

In some embodiments, the method 100B, at operation S120, may form a further contact feature over the second gate structure 25 (see contact feature 132 in FIG. 6A). Along the z direction, the length of the contact feature 131 is greater than the length of the contact feature 132. The contact feature 131 and the contact feature 132 may be formed in the same process steps. The contact features 131 and 132 with different lengths fulfill the electrical connection between the metal lines (or vias) and the stacked gate structures 14 and 25. The first gate structure 14 and the second gate structure 25 can be configured to receive different electrical signals through, e.g., the contact features 131 and 132.

FIG. 6 is a top view illustrating a semiconductor device 200C in accordance with some embodiments of the present disclosure. FIG. 6A is a cross-sectional view illustrating the semiconductor device 200C in accordance with some embodiments of the present disclosure. FIG. 6B is a cross-sectional view illustrating the semiconductor device 200C in accordance with some embodiments of the present disclosure. FIG. 6C is a cross-sectional view illustrating the semiconductor device 200C in accordance with some embodiments of the present disclosure. The structure of the semiconductor device 200C is similar to that of the semiconductor device 200A in FIGS. 3, 3A, 3B, and 3C. In some embodiments, the semiconductor device 200C may include the substrate 10, the fin structure (or the semiconductor fins) 102, the isolation structure 11, the gate dielectric layer 12, the contact feature 131, the gate structure 14, the insulation layer 20, the ESLs 211, the ILD layers 213, the contacts/vias 221, and metal lines 222. The descriptions of these semiconductor components can be referenced in relation to FIGS. 3, 3A, 3B, and 3C. The structure of the semiconductor device 200C is similar to that of the semiconductor device in FIGS. 5A-5E. In some embodiments, the semiconductor device 200C may include the second gate structure 25 and the dielectric layer 29. Therefore, some detailed descriptions may refer to corresponding preceding paragraphs and are not repeated hereinafter for conciseness.

Referring to FIG. 6, a portion of the dielectric layer 29 above the gate structure 25 is omitted to provide a clearer view of the semiconductor components that are typically covered by this layer. Another portion of the dielectric layer 29 at the same elevation with the second gate structure 25 is shown in FIG. 6. The contact feature 131 may be surrounded by the dielectric layer 29. The second gate structure 25 may be surrounded by the fin structure 102.

FIG. 6A is a cross-sectional view along the line 6A-6A′ in FIG. 6. As shown in FIG. 6A, the dielectric layer 29 has a portion disposed above the S/D features 16 and surrounding the S/D contacts 17. The top surface of the dielectric layer 29 and the top surface of the gate spacer 18 are substantially coplanar.

FIG. 6B is a cross-sectional view along the line 6B-6B′ in FIG. 6. FIG. 6C is a cross-sectional view along the line 6C-6C′ in FIG. 6.

Referring to FIG. 6B, the contact feature 132 is surrounded by the dielectric layer 29 and disposed above the second gate structure 25.

Referring to FIG. 6C, the contact feature 131 may be connected to the first gate structure 14. The contact feature 131 is spaced apart from the second gate structure 25. The contact feature 131 may be embedded in the dielectric layer 29. In some embodiments, the dielectric layer 29 may be referred to as a part of the gate dielectric layer 12 when they are made of the same or a similar material. The second gate structure 25 may include a part of the dielectric layer 19 as its gate dielectric layer. Hence, in the present disclosure, the contact feature 131 may penetrate the second gate structure 25.

Referring back to FIG. 6B, the first gate structure 14 is configured to control the first channel (or first channel region) CH1 in the fin structure 102 and the second gate structure 25 is configured to control a channel (or channel region) CH3 in the fin structure 102. The channel CH3 may extend along the dielectric layer 12. The first channel CH1 is different from the channel CH3 in terms of the location.

The channel CH3 may be generated if a voltage applied to the second gate structure 25 exceeds a threshold voltage of the second gate structure 25 and the S/D feature 16. The first gate structure 14, the first channel CH1, and the S/D features 16 may form a first transistor; and the second gate structure 25, the channel CH3, and the S/D features 16 may form a second transistor electrically connected to the first transistor in parallel.

The semiconductor device 200C includes the stacked gate structures 14 and 25, the fin structure 102, and the S/D features 16. The first gate structure 14 and the second gate structure 25 may be configured to receive electrical signals through the longer contact feature 131 and the shorter contact feature 132, respectively. The first gate structure 14 and the second gate structure 25 can be configured to control (or generate) individual channels (e.g., CH1 and CH3) between the S/D features 16. In some embodiments, the semiconductor device 200C may be a plurality of transistors electrically connected in parallel (hereinafter referred to as “parallel transistors”) of a logic gate. If at least one of the parallel transistors is turned on, the semiconductor device 200C would be turned on; only if none of the parallel transistors is generated, the semiconductor device 200C would be turned off. Semiconductor device 200C may be referred to as a dual-gate transistor. That is, the semiconductor device 200C functions as multiple transistors electrically connected in parallel but has a relatively small area. The design layout flexibility can be enhanced, enabling increased functional density.

FIG. 6D is a cross-sectional view illustrating a semiconductor device in accordance with some embodiments of the present disclosure. FIG. 6D is another cross-sectional view along the line 6B-6B′ in FIG. 6. The structure in FIG. 6D is similar to the structure of the structure in FIG. 6B. Therefore, some detailed descriptions may refer to corresponding preceding paragraphs and are not repeated hereinafter for conciseness, with differences therebetween as follows.

As shown in FIG. 6D, the isolation structure 11a may have a curved profile. The curved profile of the isolation structure 11a may be induced by the etching process. The isolation structure 11a may have a curved upper surface 11s1 in contact with the dielectric layer 12 and a curved lower surface 11s2 in contact with the substrate 10. The isolation structure 11a may include a portion 11al between the semiconductor fins 102a. The portion 11al has a curved lower surface 11s3 in contact with the substrate 10. The curved lower surface 11s3 may be at an elevation higher than that of the curved lower surface 11s2 with respect to the substrate 10.

Each of the semiconductor fins 102a may have a curved profile at its tip. The curved profile of the semiconductor fins 102a may be induced by the etching process. The first gate structure 14a may have a curved lower surface 14al facing the portion 11al of the isolation structure 11a. It can be understood that each of the embodiments illustrated in accordance with FIGS. 2A-2L, 3A-3C, 5A-5E, 6A-6D, 9A-9B, 12A-12B, and 13 may include similar profiles in the cross-sectional view, as shown in FIG. 6D.

FIG. 7 is a cross-sectional view illustrating a semiconductor device 200D in accordance with some embodiments of the present disclosure. The structure of the semiconductor device 200D is similar to the structure of the semiconductor device 200A. Therefore, some detailed descriptions may refer to corresponding preceding paragraphs and are not repeated hereinafter for conciseness, with differences therebetween as follows.

The semiconductor device 200D may include a gate structure 35 that covers semiconductor fins 112 to a greater extent than the gate structure 15 of the semiconductor device 200A. Since the gate structure 35 controls more channel regions in the semiconductor fins 112 than the first transistor of the first gate structure 14, the gate structure 35, the semiconductor fins 112, and the S/D features 16 may form a second transistor with a greater driving capacity (e.g., larger saturation current). If the semiconductor device 200D is implemented in a logic circuit, the power at the output terminal may be larger when the second transistor is turned on. This is beneficial when the next stage has a large impedance load.

FIG. 8 is a cross-sectional view illustrating a semiconductor device 200E in accordance with some embodiments of the present disclosure. The structure of the semiconductor device 200E is similar to the structure of the semiconductor device 200C. Therefore, some detailed descriptions may refer to corresponding preceding paragraphs and are not repeated hereinafter for conciseness, with differences therebetween as follows.

The semiconductor device 200E may include a first gate structure 44 and a second gate structure 45 stacked over the first gate structure 44. The stacked gate structures 44 and 45 are disposed between the fin structure 102 and the insulation layer 20. The first gate structure 44 may control a channel in only one semiconductor fin of the fin structure 102. The second gate structure 45 may control a channel in only one semiconductor fin of the fin structure 102.

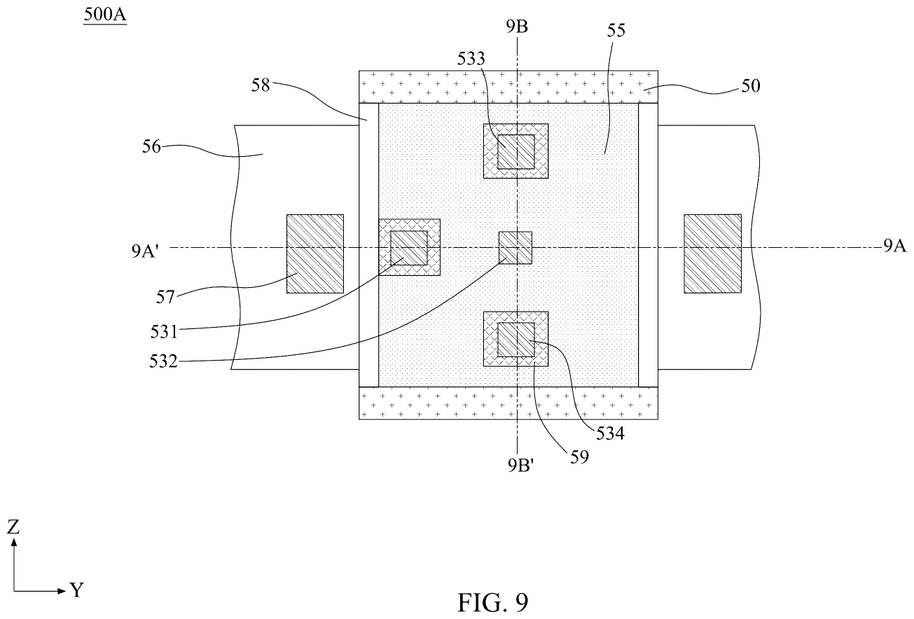

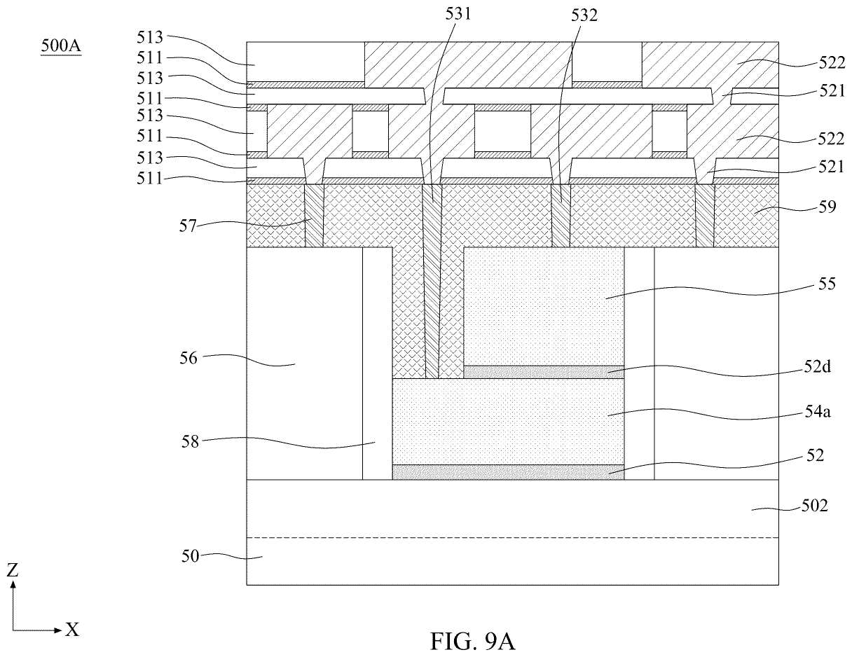

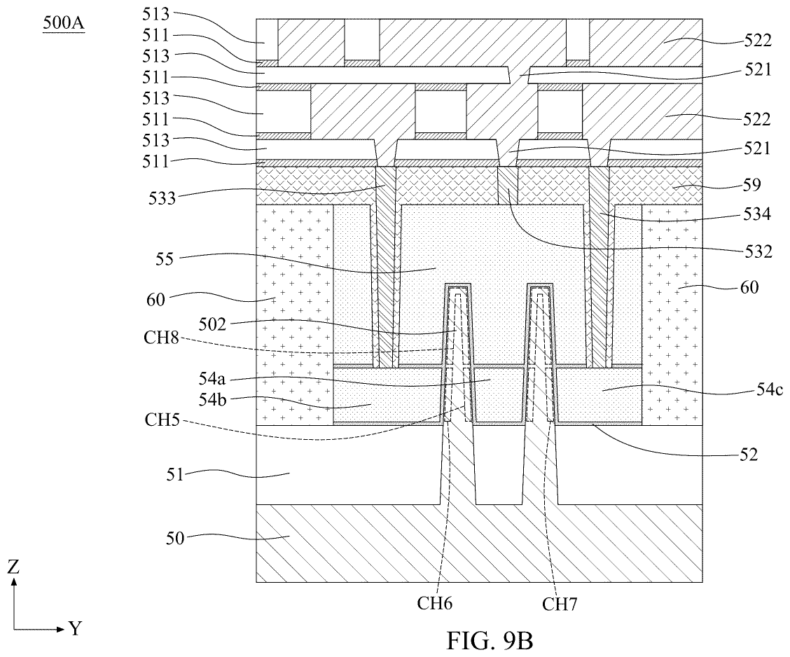

FIG. 9 is a top view illustrating a semiconductor device 500A in accordance with some embodiments of the present disclosure. FIG. 9A is a cross-sectional view illustrating the semiconductor device 500A in accordance with some embodiments of the present disclosure. FIG. 9B is a cross-sectional view illustrating the semiconductor device 500A in accordance with some embodiments of the present disclosure. The structure of the semiconductor device 500A is similar to the structure of the semiconductor device 500 in FIG. 2L. The structure of the semiconductor device 500A is similar to the structure of the semiconductor device 200A. In some embodiments, the semiconductor device 500A may include a substrate 50, a fin structure 502, an isolation structure 51, a plurality of contact features 531 and 532, a first gate structure 54a, a second gate structure 55, S/D features 56, S/D contacts 57, a gate spacer 58, a dielectric layer 59, an insulation layer 60, ESLs 511, ILD layers 513, contacts/vias 521, and metal lines 522. These semiconductor components may be similar to the corresponding semiconductor components of the semiconductor device 200A. Therefore, some detailed descriptions may refer to corresponding preceding paragraphs and are not repeated hereinafter for conciseness, with differences therebetween as follows.

Referring to FIG. 9, a portion of the dielectric layer 59 above the gate structure 55 is omitted to provide a clearer view of the semiconductor components that are typically covered by this layer. Another portion of the dielectric layer 59 at the same elevation with the second gate structure 55 is shown in FIG. 9. The semiconductor device 500A includes a contact feature 533 and a contact feature 534 surrounded by the second gate structure 55. The contact features 531, 533, and 534 are connected to different gate structures (see FIGS. 9A and 9B). In some embodiments, multiple contact features (e.g., 531, 533, and 534) are surrounded by the second gate structure 55.

FIG. 9A is a cross-sectional view along the line 9A-9A′ in FIG. 9. The first gate structure 54a is disposed below the second gate structure 55. The contact feature 531 is connected to the first gate structure 54a. The contact feature 531 may penetrate the dielectric layer 59.

FIG. 9B is a cross-sectional view along the line 9B-9B′ in FIG. 9. The contact feature 533 penetrates the second gate structure 55 and connects to a third gate structure 54b of the semiconductor device 500A. The contact feature 534 penetrates the second gate structure 55 and connects to a fourth gate structure 54c of the semiconductor device 500A. The contact feature 533 and the contact feature 534 penetrate a gate dielectric layer of the second gate structure 55. The first gate structure 54a, the third gate structure 54b, and the fourth gate structure 54c are at substantially the same elevation.

In the z direction (or a direction substantially parallel to the semiconductor fins 102), the length of the contact feature 533 is the same as that of the contact feature 534. The length of contact feature 533 is longer than that of the contact feature 532.

The first gate structure 54a is configured to control a first channel (or first channel region) CH5 in the fin structure 502; the second gate structure 55 is configured to control a second channel (or second channel region) CH8 in the fin structure 102; the third gate structure 54b is configured to control a third channel (or third channel region) CH6 in the fin structure 102; and the fourth gate structure 54c is configured to control a fourth channel (or fourth channel region) CH7 in the fin structure 102. The channels CH5, CH6, CH7, and CH8 may extend along the dielectric layer 12. The channels CH5, CH6, CH7, and CH8 are different from each other in terms of the location.

Each of the gate structures 54a, 55, 54b, and 54c, a respective channel, and S/D features 56 may form a transistor. These transistors are electrically connected in parallel. The semiconductor device 500A may be referred to as “a multiple-gate transistor.”

The stacked gate structures 54a, 55, 54b, and 54c may be configured to receive electrical signals through the longer contact feature 531, the shorter contact feature 532, the longer contact feature 533, and the longer contact feature 534, respectively. The stacked gate structures 54a, 55, 54b, and 54c can be configured to control (or generate) individual channels (e.g., CH5-CH8) between the S/D features 16. In some embodiments, the semiconductor device 500A may be a plurality of transistors electrically connected in parallel (hereinafter referred to as “parallel transistors”) of a logic gate. If at least one of the parallel transistors is turned on, the semiconductor device 500A would be turned on; only if none of the parallel transistors is generated, the semiconductor device 500A would be turned off. That is, the semiconductor device 500A functions as multiple transistors electrically connected in parallel but has a relatively small area. The design layout flexibility can be enhanced, enabling increased functional density.

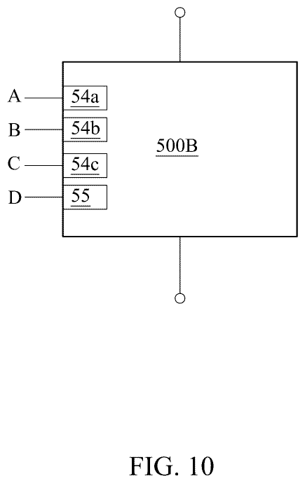

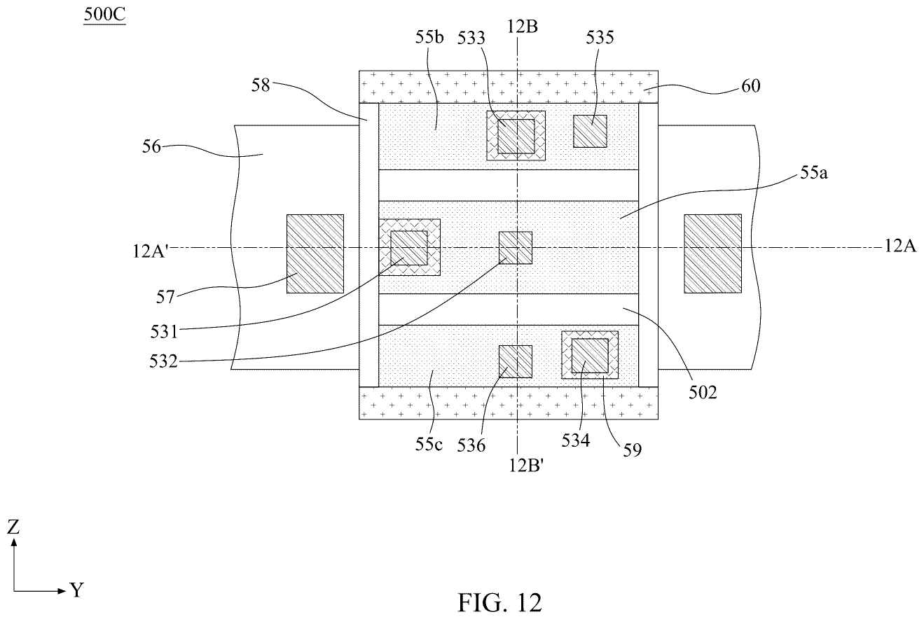

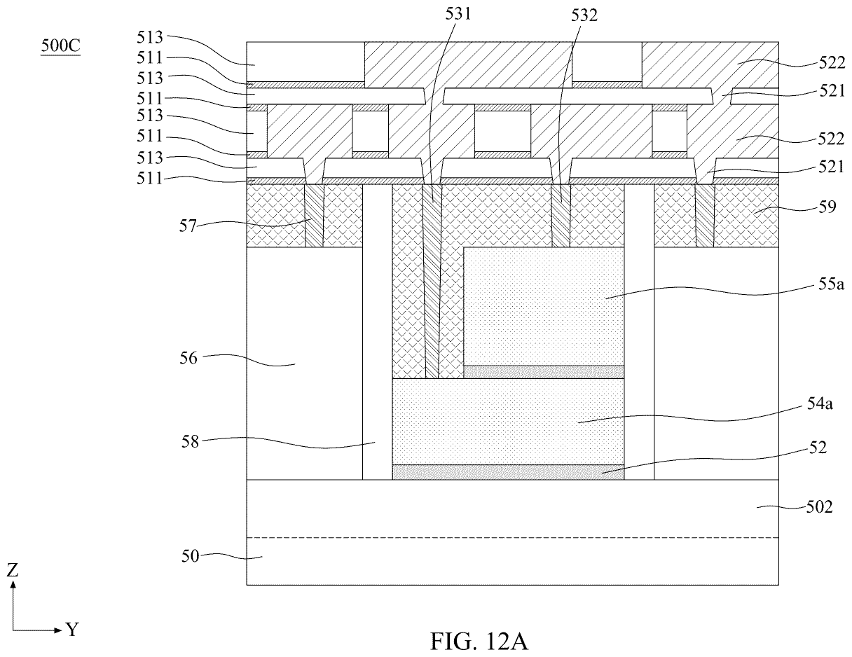

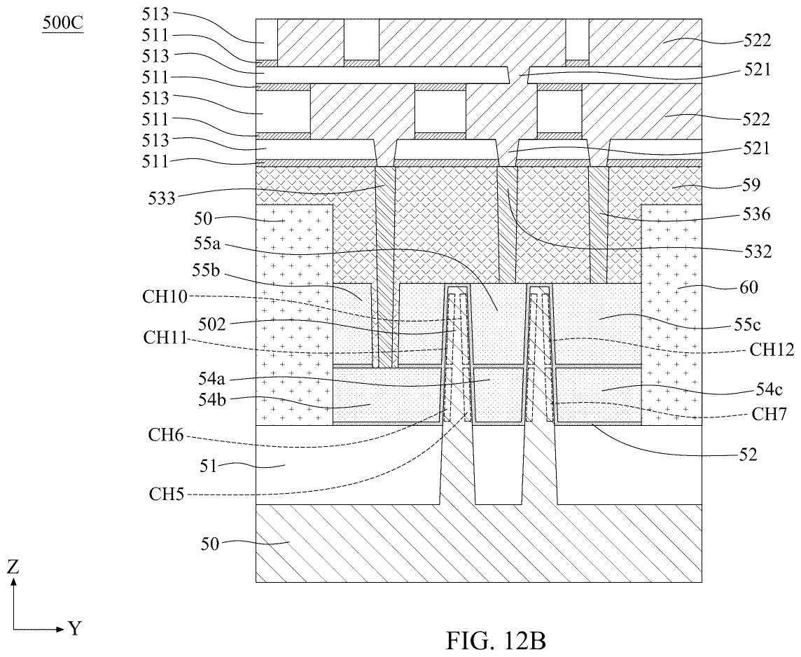

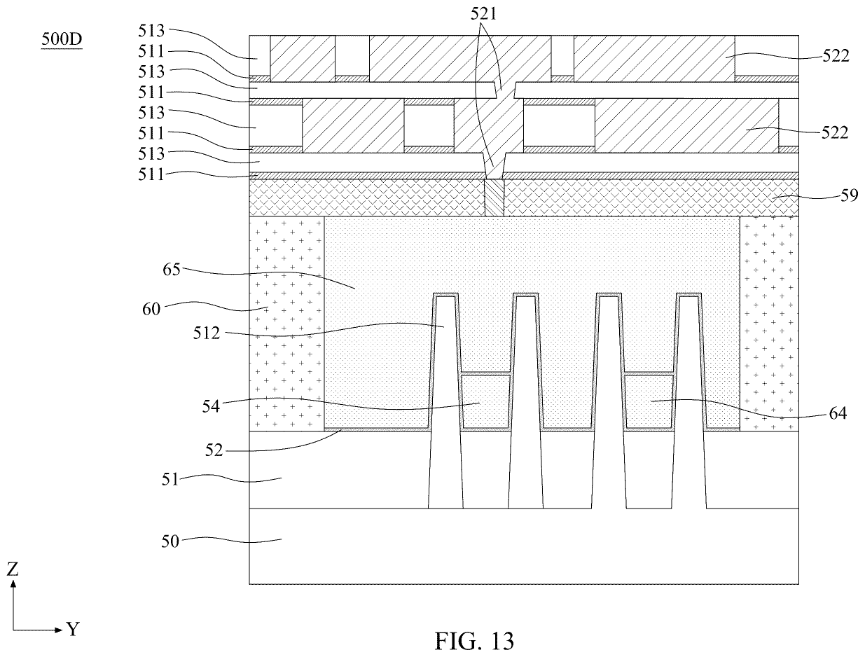

FIG. 10 is a schematic diagram illustrating a semiconductor device (or multiple-gate transistor) 500B in accordance with some embodiments of the present disclosure. The semiconductor device 500B may be the semiconductor device 500 in FIG. 2L, the semiconductor device 500A in FIGS. 9-9B, the semiconductor device 500C in FIGS. 12-12B, and the semiconductor device 500D in FIG. 13.

Each of the gate structures 54a, 55, 54b, and 54c is one of the multiple gates of the semiconductor device 500B. The gate structures 54a, 55, 54b, and 54c, may be configured to receive signals A, B, C, and D, independent of each other. The semiconductor device 500B may be a multiple-gate n-type transistor. If signals A, B, C, and D are 0 (“logic low”), the semiconductor device 500B is off. If at least one of signals A, B, C, and D is 1 (“logic high”), the semiconductor device 500B is on. The semiconductor device 500B may be a multiple-gate p-type transistor. If signals A, B, C, and D are 1 (“logic high”), the semiconductor device 500B is off. If at least one of signals A, B, C, and Dis 0 (“logic low”), the semiconductor device 500B is on.

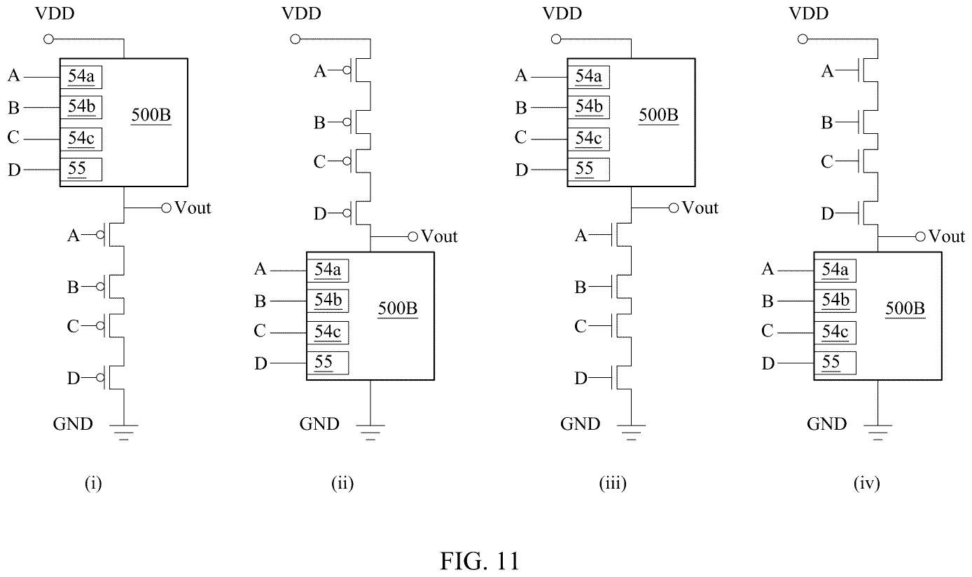

The semiconductor device (or the multiple-gate transistor) 500B may be connected to transistors to form logic gates (e.g., OR gate, NOR gate, AND gate, or NAND gate). FIG. 4B illustrates circuit diagrams of a device (e.g., OR gate, NOR gate, AND gate, or NAND gate) including the semiconductor device 500B in accordance with some embodiments of the present disclosure. FIG. 11 illustrates circuit diagrams of devices (e.g., OR gate, NOR gate, AND gate, or NAND gate) including the semiconductor device 500B in accordance with some embodiments of the present disclosure.

As shown in (i) of FIG. 11, the semiconductor device 500B may be a multiple-gate n-type transistor having a first terminal connected to a voltage supply VDD, and a second terminal connected to a plurality of p-type transistors, which are connected in series (hereinafter referred to as “series p-type transistors”). The series p-type transistors are connected to the ground GND. The truth table of the device (OR gate) in (i) is presented in Table 5:

TABLE 5

| A | B | C | D | Vout |
|---|---|---|---|---|
| 0 | 0 | 0 | 0 | 0 |
| 1 | 0 | 0 | 0 | 1 |
| 1 | 1 | 0 | 0 | 1 |
| 1 | 1 | 1 | 0 | 1 |
| 1 | 1 | 1 | 1 | 1 |

As shown in (ii) of FIG. 11, the semiconductor device 500B may be a multiple-gate n-type transistor having a first terminal connected to the ground GND, and a second terminal connected to series p-type transistors, which are connected to the voltage supply VDD. The truth table of the device (NOR gate) in (ii) is presented in Table 6:

TABLE 6

| A | B | C | D | Vout |
|---|---|---|---|---|
| 0 | 0 | 0 | 0 | 1 |
| 1 | 0 | 0 | 0 | 0 |
| 1 | 1 | 0 | 0 | 0 |
| 1 | 1 | 1 | 0 | 0 |
| 1 | 1 | 1 | 1 | 0 |

As shown in (iii) of FIG. 11, the semiconductor device 500B may be a multiple-gate p-type transistor having a first terminal connected to a voltage supply VDD, and a second terminal connected to a plurality of n-type transistors, which are connected in series (hereinafter referred to as “series n-type transistors”). The series n-type transistors are connected to the ground GND. The truth table of the device (NAND gate) in (i) is presented in Table 7:

TABLE 7

| A | B | C | D | Vout |
|---|---|---|---|---|
| 0 | 0 | 0 | 0 | 1 |
| 1 | 0 | 0 | 0 | 1 |
| 1 | 1 | 0 | 0 | 1 |
| 1 | 1 | 1 | 0 | 1 |
| 1 | 1 | 1 | 1 | 0 |

As shown in (iv) of FIG. 11, the semiconductor device 500B may be a multiple-gate p-type transistor having a first terminal connected to the ground GND, and a second terminal connected to series n-type transistors, which are connected to the voltage supply VDD. The truth table of the device (AND gate) in (ii) is presented in Table 8:

TABLE 8

| A | B | C | D | Vout |
|---|---|---|---|---|
| 0 | 0 | 0 | 0 | 0 |
| 1 | 0 | 0 | 0 | 0 |
| 1 | 1 | 0 | 0 | 0 |
| 1 | 1 | 1 | 0 | 0 |
| 1 | 1 | 1 | 1 | 1 |

In some cases, building logic gates by incorporating multiple transistors electrically connected in parallel would occupy a relatively large area, thereby limiting design layout flexibility and reducing functional density. In the present disclosure, the semiconductor device (or multiple-gate transistor) 500B (or 500, 500A, 500C, 500D) having the function of parallel transistors, occupies a relatively small area. The design layout flexibility can be enhanced, enabling increased functional density.

FIG. 12 is a top view illustrating a semiconductor device 500C in accordance with some embodiments of the present disclosure. FIG. 12A is a cross-sectional view illustrating the semiconductor device 500C in accordance with some embodiments of the present disclosure. FIG. 12B is a cross-sectional view illustrating the semiconductor device 500C in accordance with some embodiments of the present disclosure. The structure of the semiconductor device 500C is similar to the structure of the semiconductor device 500A in FIGS. 9, 9A, and 9B. In some embodiments, the semiconductor device 500C may include the substrate 50, the fin structure (or the semiconductor fins) 502, the isolation structure 51, the gate dielectric layer 52, the contact features 531, 532, 533, and 534, the gate structures 54a, 54b, and 54c, the insulation layer 60, the ESLs 511, the ILD layers 513, the contacts/vias 521, and metal lines 522. The descriptions of these semiconductor components can be referenced in relation to FIGS. 9, 9A, and 9B. Therefore, some detailed descriptions may refer to corresponding preceding paragraphs and are not repeated hereinafter for conciseness.

Referring to FIG. 12, a portion of the dielectric layer 59 above the gate structures 55a, 55b, and 55b is omitted to provide a clearer view of the semiconductor components that are typically covered by this layer. Another portion of the dielectric layer 59 at the same elevation with the second gate structures 55a, 55b, and 55c is shown in FIG. 9. The second gate structure 55a may be surrounded by the fin structure 502. The semiconductor device 500C includes a fifth gate structure 55b and a sixth gate structure 55c. The fifth gate structure 55b is separated from the second gate structure 55a by the fin structure 502. The sixth gate structure 55c is separated from the second gate structure 55a by the fin structure 502. The semiconductor device 500C includes a contact feature 535 disposed above the fifth gate structure 55b and a contact feature 536 disposed above the sixth gate structure 55c. The contact feature 535 is connected to the fifth gate structure 55b. The contact feature 536 is connected to the sixth gate structure 55c.

The contact feature 533 may be surrounded by the fifth gate structure 55b. The contact feature 534 may be surrounded by the sixth gate structure 55c.

FIG. 12A is a cross-sectional view along the line 12A-12A′ in FIG. 12. As shown in FIG. 12A, the dielectric layer 59 has a portion disposed above the S/D features 56 and surrounding the S/D contacts 57. The top surface of the dielectric layer 59 and the top surface of the gate spacer 58 are substantially coplanar.

FIG. 12B is a cross-sectional view along the line 12B-12B′ in FIG. 12. As shown in FIG. 12B, the contact feature 536 is surrounded by the dielectric layer 59 and disposed above the sixth gate structure 55c. The contact feature 535 is surrounded by the dielectric layer 59. The contact feature 535 may be partially surrounded by the fifth gate structure 55b. The contact feature 535 may be connected to the third gate structure 54b. The contact feature 535 is spaced apart from the fifth gate structure 55b. The contact feature 535 may be embedded in the dielectric layer 59. In some embodiments, the dielectric layer 59 may be referred to as a part of the gate dielectric layer 52 when they are made of the same or a similar material. The fifth gate structure 55b may include a part of the dielectric layer 59 as its gate dielectric layer. Hence, in the present disclosure, the contact feature 535 may penetrate the fifth gate structure 55.

The first gate structure 54a is configured to control a first channel (or first channel region) CH5 in the fin structure 502; the second gate structure 55b is configured to control a second channel (or second channel region) CH10 in the fin structure 502; the third gate structure 54b is configured to control a third channel (or third channel region) CH6 in the fin structure 102; the fourth gate structure 54c is configured to control a fourth channel (or fourth channel region) CH7 in the fin structure 102; the fifth gate structure 55b is configured to control a fifth channel (or fifth channel region) CH11 in the fin structure 502; and the sixth gate structure 55c is configured to control a sixth channel (or sixth channel region) CH12 in the fin structure 502. The channels CH5, CH6, CH7, CH10, CH11, and CH12 may extend along the dielectric layer 12. The channels CH5, CH6, CH7, CH10, CH11, and CH12 are different from each other in terms of the location.

Each of the gate structures 54a, 54b, 54c, 55a, 55b, and 55c, a respective channel, and S/D features 56 may form a transistor. These transistors are electrically connected in parallel. The semiconductor device 500A may be referred to as “a multiple-gate transistor.”

The stacked gate structures 54a, 54b, 54c, 55a, 55b, and 55c may be configured to receive electrical signals through the contact features 531, 535, 536, 532, 533, and 534, respectively. The stacked gate structures 54a, 54b, 54c, 55a, 55b, and 55c can be configured to control (or generate) individual channels (e.g., CH5-CH7 and CH10-CH12) between the S/D features 56. In some embodiments, the semiconductor device 500C may be a plurality of transistors electrically connected in parallel (hereinafter referred to as “parallel transistors”) of a logic gate. If at least one of the parallel transistors is turned on, the semiconductor device 500C would be turned on; only if none of the parallel transistors is generated, the semiconductor device 500C would be turned off. That is, the semiconductor device 500C functions as multiple transistors electrically connected in parallel but has a relatively small area. The design layout flexibility can be enhanced, enabling increased functional density.

FIG. 13 is a cross-sectional view illustrating a semiconductor device 500D in accordance with some embodiments of the present disclosure. The structure of the semiconductor device 500D is similar to the structure of the semiconductor device 500A. Therefore, some detailed descriptions may refer to corresponding preceding paragraphs and are not repeated hereinafter for conciseness, with differences therebetween as follows.

The semiconductor device 500D may include a gate structure 65 covering more semiconductor fins 512 than the gate structure 55 of the semiconductor device 500A. Since the gate structure 65 controls more channel regions in the semiconductor fins 112 than the first transistor of the first gate structure, the gate structure 65, the semiconductor fins 112, and the S/D features 56 may form a second transistor with a greater driving capacity (e.g., larger saturation current). If the semiconductor device 500D is implemented in a logic circuit, the power at the output terminal may be larger when the second transistor is turned on. This is beneficial when the next stage has a large impedance load.

The semiconductor device 500D may include a gate structure 64 disposed below the gate structure 65. The gate structure 64 is spaced apart from the gate structure 54. The gate structure 64 and the gate structure 54 are at substantially the same elevation. The gate structure 64 may be configured to control a channel (channel region) in the fin structure 512. Each of the gate structures 54, 64, and 65, and a respective channel, and the S/D features 56 may form a transistor. These transistors are electrically connected in parallel. The semiconductor device 500D may be referred to as a tri-gate transistor. That is, the semiconductor device 500D functions as three transistors electrically connected in parallel but has a relatively small area. The design layout flexibility can be enhanced, enabling increased functional density.

According to other embodiments, a method of manufacturing a semiconductor device is provided. The method includes: providing the semiconductor device comprising a fin structure protruding from a substrate, wherein a gate trench is between adjacent fins of the fin structure; forming a first gate structure in the first gate trench; and forming a second gate structure above in the first gate trench and the first gate structure.

According to other embodiments, a method of manufacturing a semiconductor device is provided. The method includes: forming a first gate structure; forming a second gate structure above the first gate structure; and forming a first contact feature penetrating the second gate structure to connect the first gate structure.

According to other embodiments, a semiconductor device is provided. The semiconductor device includes a first gate structure, a second gate structure, and a first contact feature. The second gate structure is disposed above the first gate structure. The first contact feature is connected to the first gate structure. The first contact feature penetrates the second gate structure.

The methods and features of the present disclosure have been sufficiently described in the above examples and descriptions. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, and compositions of matter, means, methods or steps. In addition, each claim constitutes a separate embodiment, and the combination of various claims and embodiments are within the scope of the present disclosure.

What is claimed is:

1. A method of manufacturing a semiconductor device, comprising:
providing the semiconductor device comprising a fin structure protruding from a substrate, wherein a first gate trench is between adjacent fins of the fin structure;
forming a first gate structure in the first gate trench; and
forming a second gate structure in the first gate trench and above the first gate structure.

2. The method of claim 1, further comprising: prior to the forming of the second gate structure, forming an oxide layer on the first gate structure for separating the first gate structure from the second gate structure.

3. The method of claim 1, wherein the second gate structure comprises a first portion of in the first gate trench and a second portion outside the first gate trench.

4. The method of claim 1, wherein the second portion of the second gate structure surrounds the fin structure.

5. The method of claim 1, wherein a second gate trench separated from the first gate trench is between second adjacent fins of the fin structure.

6. The method of claim 5, further comprising:
forming a third gate structure in the second gate trench, wherein the first gate structure and the third gate structure are at the same elevation.

7. The method of claim 1, wherein the first gate structure and the second gate structure are configured to receive different electrical signals.

8. The method of claim 1, wherein the first gate structure and the fin structure collectively form a part of a first transistor, and the second gate structure and the fin structure collectively forma part of a second transistor, and the first transistor and the second transistor are electrically connected in parallel.

9. A method of manufacturing a semiconductor device, comprising:
forming a first gate structure;
forming a second gate structure above the first gate structure; and
forming a first contact feature penetrating the second gate structure to connect the first gate structure.

10. The method of claim 9, further comprising:
forming a first opening in the second gate structure prior to forming the first contact feature; and
forming a dielectric layer in the first opening.

11. The method of claim 10, further comprising:
forming a second opening in the dielectric layer to partially expose the first gate structure; and
forming the first contact feature in the second opening.

12. The method of claim 11, wherein the dielectric layer is above the second gate structure and penetrated by the first contact feature.

13. The method of claim 9, further comprising forming a second contact feature to connect the second gate structure, wherein a first length of the first contact feature is greater than a second length of the second contact feature.

14. The method of claim 13, further comprising:
forming a first via connecting to the first contact feature; and
forming a second via connecting to the second contact feature.

15. The method of claim 9, wherein the second gate structure comprises a gate dielectric layer penetrated by the first contact feature.

16. A semiconductor device, comprising:
a first gate structure;
a second gate structure disposed above the first gate structure; and
a first contact feature connected to the first gate structure,
wherein the first contact feature penetrates the second gate structure.

17. The semiconductor device of claim 16, wherein the first gate structure is separated from the second gate structure.

18. The semiconductor device of claim 16, wherein the first contact feature is surrounded by the second gate structure.

19. The semiconductor device of claim 16, further comprising a gate spacer interfacing with the first gate structure and the second gate structure.

20. The semiconductor device of claim 16, further comprising:
a fin structure surrounding at least one of the first gate structure and the second gate structure,
wherein the first gate structure is configured to control a first channel in the fin structure and the second gate structure is configured to control a second channel in the fin structure.
